(19) United States
(12) Patent Application Publication
(10) Pub. No.: US 2025/0113616 A1
(43) Pub. Date: Apr. 3, 2025

(54) DISPLAY DEVICE AND METHOD OF MANUFACTURING DISPLAY DEVICE

(71) Applicant: Japan Display Inc., Tokyo (JP)

(72) Inventors: Akihiro HANADA, Tokyo (JP); Takuo KAITOH, Tokyo (JP); Motochika YUKAWA, Tokyo (JP)

(73) Assignee: Japan Display Inc., Tokyo (JP)

(21) Appl. No.: 18/884,253

(22) Filed: Sep. 13, 2024

(30) Foreign Application Priority Data
Sep. 28, 2023 (JP) 2023-168450

(51) Int. Cl. H01L 27/12; G02F 1/1368

(52) U.S. Cl. CPC H10D 86/60; G02F 1/1368; H10D 86/0221; H10D 86/423; H10D 86/451

(57) ABSTRACT

A display device includes an oxide semiconductor layer including a polycrystalline structure, a gate insulating layer provided on the oxide semiconductor layer, a gate electrode opposite to the oxide semiconductor layer on the gate insulating layer, a first silicon nitride layer provided in contact with the gate electrode, a source wiring provided in contact with the first silicon nitride layer and electrically connected to the oxide semiconductor layer, a second silicon nitride layer provided in contact with the source wiring and the first silicon nitride layer, a first transparent conductive layer provided in contact with the second silicon nitride layer and electrically connected to the oxide semiconductor layer, and a third silicon nitride layer provided in contact with the first transparent conductive layer and the second silicon nitride layer, wherein a channel length of the gate electrode is 2.0 μm or less.

### CROSS-REFERENCE TO RELATED APPLICATIONS

This application claims the benefit of priority to Japanese Patent Application No. 2023-168450, filed on Sep. 28, 2023, the entire contents of which are incorporated herein by reference.

### FIELD

An embodiment of the present invention relates to a display device and a method of manufacturing the display device. In particular, an embodiment of the present invention relates to a display device using a transistor having an oxide semiconductor and a method of manufacturing the display device.

### BACKGROUND

Recently, a transistor using an oxide semiconductor for a channel instead of amorphous silicon, low-temperature polysilicon, and single-crystal silicon has been developed (for example, Japanese laid-open patent publication No. 2014-146819 and Japanese laid-open patent publication No. 2015-159315). Similar to the transistor using amorphous silicon for a channel, the transistor using the oxide semiconductor for the channel is simply structured and formed by low-temperature processing. The transistor using the oxide semiconductor for the channel is known to have higher mobility and a much lower off-state current than the transistor using amorphous silicon for the channel.

Furthermore, in recent years, a display device has been required to have high definition, and pixel size reduction has been promoted. With the reduction in pixel size, the reduction in wiring width and transistor size has been studied. However, this reduction is limited, and the aperture ratio is reduced due to the arrangement of a metal layer and a semiconductor layer constituting a pixel circuit. Therefore, a transistor in which the oxide semiconductor layer, which can have sufficient properties for driving the pixel circuit even if the transistor size is small, is used for the channel has been developed for use in a transistor of the pixel circuit.

### SUMMARY

A display device according to an embodiment of the present invention includes an oxide semiconductor layer including a polycrystalline structure, a gate insulating layer provided on the oxide semiconductor layer, a gate electrode opposite to the oxide semiconductor layer on the gate insulating layer, a first silicon nitride layer provided in contact with the gate electrode, a source wiring provided in contact with the first silicon nitride layer and electrically connected to the oxide semiconductor layer, a second silicon nitride layer provided in contact with the source wiring and the first silicon nitride layer, a first transparent conductive layer provided in contact with the second silicon nitride layer and electrically connected to the oxide semiconductor layer, and a third silicon nitride layer provided in contact with the first transparent conductive layer and the second silicon nitride layer, wherein a channel length of the gate electrode is 2.0 μm or less.

A display device according to an embodiment of the present invention includes an oxide semiconductor layer including a polycrystalline structure, a gate insulating layer provided on the oxide semiconductor layer, a gate electrode opposite to the oxide semiconductor layer on the gate insulating layer, a first silicon nitride layer provided in contact with the gate electrode, a silicon oxide layer provided in contact with the first silicon nitride layer, a source wiring provided in contact with the silicon oxide layer and electrically connected to the oxide semiconductor layer, and a second silicon nitride layer provided in contact with the source wiring and the first silicon nitride layer, a first transparent conductive layer provided in contact with the second silicon nitride layer and electrically connected to the oxide semiconductor layer, and a third silicon nitride layer provided in contact with the first transparent conductive layer and the second silicon nitride layer, wherein a channel length of the gate electrode is less than 2.0 μm, and a thickness of the silicon oxide layer is less than each of a thickness of the first silicon nitride layer, a thickness of the second silicon nitride layer, and a thickness of the third silicon nitride layer.

A method of manufacturing a display device according to an embodiment of the present invention, the method comprising steps of: forming an oxide semiconductor layer including a polycrystalline structure; depositing a gate insulating layer on the oxide semiconductor layer; forming a gate electrode opposite to the oxide semiconductor layer on the gate insulating layer; depositing a first silicon nitride layer in contact with the gate electrode; forming a source wiring in contact with the first silicon nitride layer, and electrically connected to the oxide semiconductor layer; forming a second silicon nitride layer in contact with the source wiring and the first silicon nitride layer; forming a first transparent conductive layer in contact with the second silicon nitride layer, and electrically connected to the oxide semiconductor layer; and depositing a third silicon nitride layer in contact with the first transparent conducting layer and the second silicon nitride layer. A channel length of a channel region overlapping the gate electrode is 2.0 μm or less, in the oxide semiconductor layer, and a deposition temperature of each of the first silicon nitride layer, the second silicon nitride layer, and the third silicon nitride layer is 150° C. or more and 250° C. or less.

### DESCRIPTION OF DRAWINGS

FIG. 1 is a schematic plan view showing a configuration of a display device according to an embodiment of the present invention.

FIG. 2 is a schematic plan view showing a circuit configuration of a display device according to an embodiment of the present invention.

FIG. 3 is a circuit diagram showing a pixel circuit of a pixel of a display device according to an embodiment of the present invention.

FIG. 4 is a cross-sectional view showing an outline of a display device according to an embodiment of the present invention.

FIG. 5 is a plan view showing a configuration of a pixel of a display device according to an embodiment of the present invention.

FIG. 6 is a plan view showing a configuration of a pixel of a display device according to an embodiment of the present invention.

FIG. 7 is a sequence diagram illustrating a method of manufacturing a display device according to an embodiment of the present invention.

FIG. 8 is a sequence diagram illustrating a method of manufacturing a display device according to an embodiment of the present invention.

FIG. 9 is a cross-sectional view illustrating a method of manufacturing a display device according to an embodiment of the present invention.

FIG. 10 is a cross-sectional view illustrating a method of manufacturing a display device according to an embodiment of the present invention.

FIG. 11 is a cross-sectional view illustrating a method of manufacturing a display device according to an embodiment of the present invention.

FIG. 12 is a cross-sectional view illustrating a method of manufacturing a display device according to an embodiment of the present invention.

FIG. 13 is a cross-sectional view illustrating a method of manufacturing a display device according to an embodiment of the present invention.

FIG. 14 is a cross-sectional view illustrating a method of manufacturing a display device according to an embodiment of the present invention.

FIG. 15 is a cross-sectional view illustrating a method of manufacturing a display device according to an embodiment of the present invention.

FIG. 16 is a cross-sectional view illustrating a method of manufacturing a display device according to an embodiment of the present invention.

FIG. 17 is a cross-sectional view illustrating a method of manufacturing a display device according to an embodiment of the present invention.

FIG. 18 is a cross-sectional view showing an outline of a display device according to an embodiment of the present invention.

FIG. 19 is a sequence diagram illustrating a method of manufacturing a display device according to an embodiment of the present invention.

FIG. 20 is a cross-sectional view illustrating a method of manufacturing a display device according to an embodiment of the present invention.

FIG. 21 is a cross-sectional view illustrating a method of manufacturing a display device according to an embodiment of the present invention.

FIG. 22 is a cross-sectional view showing an outline of a display device according to an embodiment of the present invention.

FIG. 23 is a cross-sectional view illustrating a method of manufacturing a display device according to an embodiment of the present invention.

FIG. 24 is a cross-sectional view showing an outline of a display device according to an embodiment of the present invention.

FIG. 25 is a sequence diagram illustrating a method of manufacturing a display device according to an embodiment of the present invention.

FIG. 26 is a sequence diagram illustrating a method of manufacturing a display device according to an embodiment of the present invention.

### DESCRIPTION OF EMBODIMENTS

It is known that a transistor using an oxide semiconductor is greatly affected by hydrogen contained in an insulating film arranged around the oxide semiconductor. With the reduction in pixel size of a display device, the size of the transistor (a channel length L) needs to be reduced. In the case where the channel length L is 2.0 μm or less, hydrogen is likely to penetrate not only a source region and drain region but also a channel region, which may cause the transistor to fail to operate.

An object of an embodiment of the present invention is to provide a high-definition display device.

Hereinafter, embodiments of the present invention will be described with reference to the drawings. The following disclosure is merely an example. A configuration that can be easily conceived by a person skilled in the art by appropriately changing the configuration of the embodiment while keeping the gist of the invention is naturally included in the scope of the present invention. For clarity of explanation, the drawings may be schematically represented with respect to widths, film thicknesses, shapes, and the like of respective portions as compared with actual embodiments. However, the illustrated shapes are merely examples, and do not limit the interpretation of the present invention. In the present specification and the drawings, the same reference signs are given to the same components as those described previously with respect to the above-described drawings, and detailed description thereof may be omitted as appropriate.

“Semiconductor device” refers to a device that can function by utilizing semiconductor properties. A transistor and a semiconductor circuit are one form of a semiconductor device. For example, the semiconductor device may be an integrated circuit (IC) such as a display device or a micro-processing unit (MPU), or a transistor used in a memory circuit.

“Display device” refers to a structure that displays an image using an electro-optical layer. For example, the terms display device may refer to a display panel that includes the electro-optical layer, or may refer to a structure with other optical members (for example, a polarized member, a backlight, a touch panel, and the like) attached to a display cell. “Electro-optical layer” may include a liquid crystal layer, an electroluminescent (EL) layer, an electrochromic (EC) layer, or an electrophoretic layer, unless there is no technical contradiction. Therefore, for the embodiments described later, although a liquid crystal display device including the liquid crystal layer and an organic EL display device including the organic EL layer is exemplified for the explanation of the display device, the structure according to the embodiment can be applied to a display device including the other electro-optical layers described above.

In the embodiments of the present invention, a direction from a substrate toward an oxide semiconductor layer is referred to as upper or above. Conversely, a direction from the oxide semiconductor layer to the substrate is referred to as lower or below. In this way, for convenience of explanation, the phrase “above” or “below” is used for the purposes of explanation, but for example, the substrate and the oxide semiconductor layer may be arranged so that the upper and lower relationship is different from the drawings. In the following explanation, for example, the expression “oxide semiconductor layer on the substrate” merely describes the upper and lower relationship between the substrate and the oxide semiconductor layer as described above, and another member may be arranged between the substrate and the oxide semiconductor layer. The terms “above” or “below” mean a stacking order in which a plurality of layers is stacked, and may be a positional relationship in which the transistor does not overlap a pixel electrode in a plan view when expressed as a pixel electrode above the transistor. On the other hand, when expressed as a pixel electrode vertically above the transistor, it means a positional relationship in which the transistor overlaps the pixel electrode in a plan view.

In the present specification, the phrases “a includes A, B or C,” “a includes any of A, B and C,” “a includes one selected from a group consisting of A, B and C,” and the like do not exclude the case where a includes a plurality of combinations of A to C unless otherwise indicated. Furthermore, these expressions do not exclude the case where a includes other elements.

In addition, the following embodiments can be combined with each other as long as there is no technical contradiction.

### First Embodiment

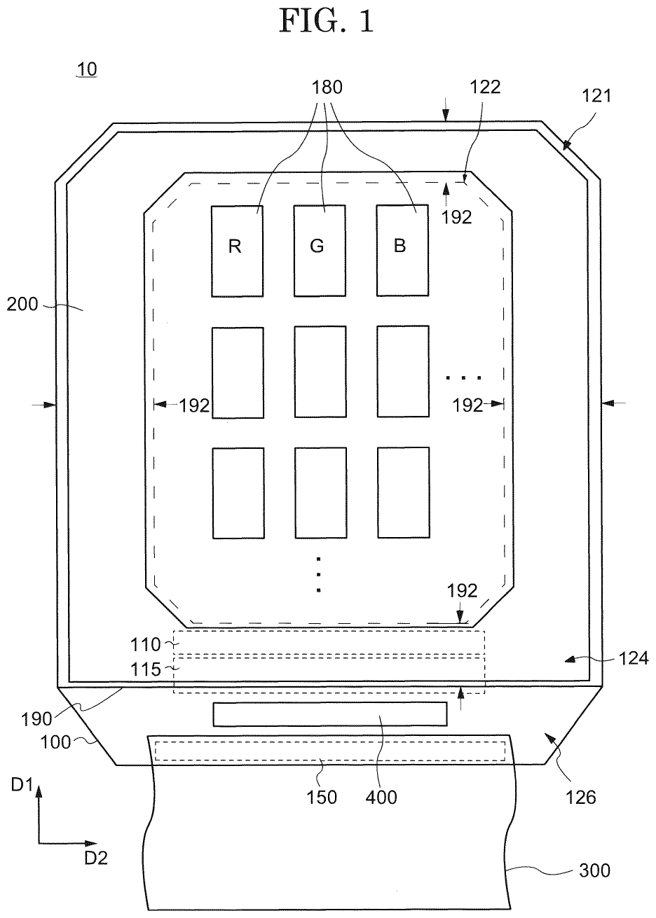

A display device 10 according to an embodiment of the present invention will be described with reference to FIG. 1 to FIG. 26.

### [1. Outline of Display Device]

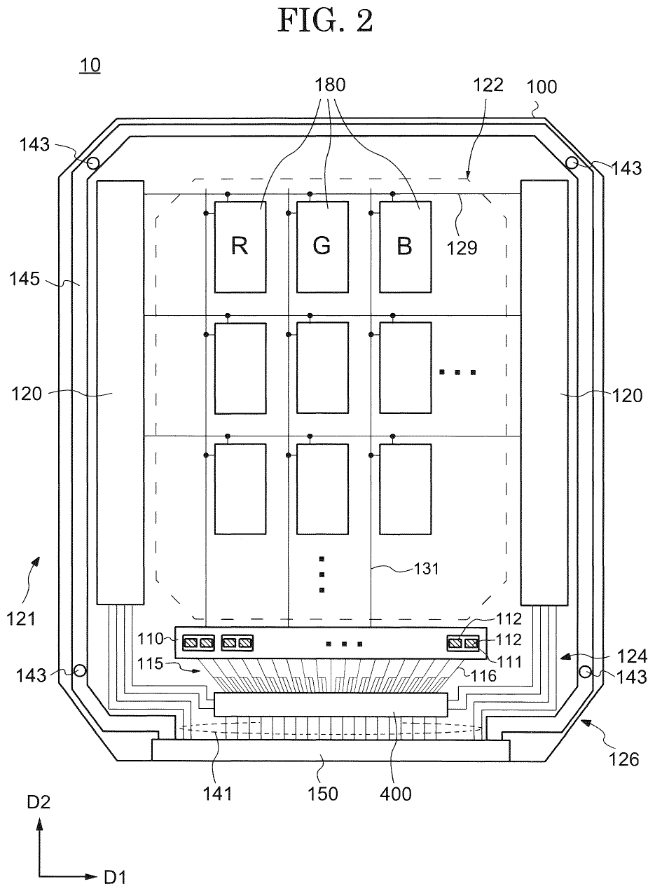

An outline of the display device 10 will be described with reference to FIG. 1 and FIG. 2. FIG. 1 is a schematic plan view showing a configuration of the display device 10. FIG. 2 is a schematic plan view showing a circuit configuration of the display device 10. For example, the display device 10 is a liquid crystal display device.

As shown in FIG. 1 or FIG. 2, the display device 10 includes an array substrate 100, a seal part 200, a counter substrate 190, a flexible printed circuit board (FPC) 300, and an IC chip 400. The array substrate 100 and the counter substrate 190 are bonded together by the seal part 200.

In addition, the display device 10 includes a display region 122 and a peripheral region 121 surrounding the display region 122. The peripheral region 121 includes a sealing region 124 and the outside of the sealing region 124 surrounding the sealing region 124. The outside of the sealing region 124 includes an exposed region 126.

A plurality of pixels 180 arranged in a matrix in a first direction D1 and a second direction D2 is arranged in the display region 122. The display region 122 is a region that overlaps a liquid crystal layer (not shown) containing liquid crystal molecules in a plan view.

A shielding part 192 overlapping the array substrate 100 and the counter substrate 190 is arranged in the peripheral region 121. The seal part 200 is arranged in the sealing region 124. The sealing region 124 is a region that overlaps the seal part 200 in a plan view.

The exposed region 126 is a region where the array substrate 100 is exposed from the counter substrate 190. An FPC terminal part 150 is arranged in the exposed region 126. Part of the FPC 300, the IC chip 400, and a wiring part 115 are arranged in the exposed region 126.

The sealing region 124, the outside of the sealing region 124, and the exposed region 126 may be collectively referred to as a frame region in the display device 10.

The FPC terminal part 150 includes a plurality of FPC terminals. The wiring part 115 includes a plurality of data signal source lines 116. The shielding part 192 overlaps the seal part 200, a first driver circuit 110, a second driver circuit 120, part of the wiring part 115, and a common wiring 145, and has a function of hiding the seal part 200, the first driver circuit 110, the second driver circuit 120, part of the wiring part 115, the common wiring 145, and the like.

The case where the shape of the array substrate 100 of the display device 10 and the shape of the display region 122 are octagonal will be described. In addition, the shape of the array substrate 100 of the display device 10 and the shape of the display region 122 are not limited to octagonal and may be rectangular or circular.

### [2. Circuit Configuration of Display Device 10]

Next, a circuit configuration of the display device 10 will be described with reference to FIG. 2. Configurations that are the same as or similar to those in FIG. 1 will be described as necessary.

As shown in FIG. 2, the FPC terminal part 150 connected to the FPC 300 is connected to the IC chip 400 and the second driver circuit 120 by a connecting wiring 141. The IC chip 400 is connected to the first driver circuit 110 using the plurality of data signal source lines 116.

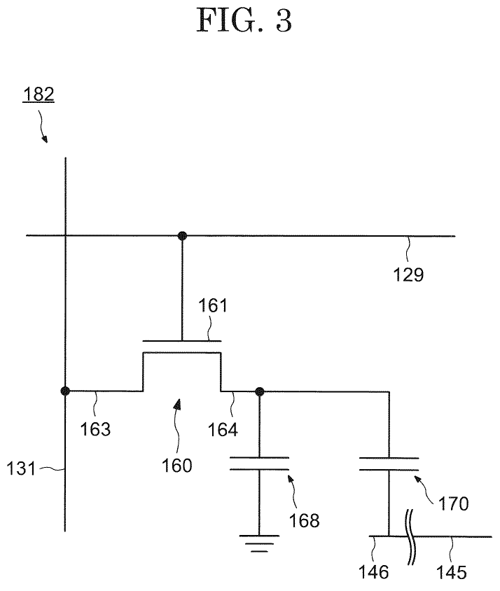

The first driver circuit 110 is arranged parallel to the first direction D1 of the display region 122. In addition, the second driver circuit 120 is arranged parallel to the second direction D2 of the display region 122. The first driver circuit 110 and the second driver circuit 120 overlap the sealing region 124 (FIG. 1) in a plan view. The region where the sealing region 124 overlaps the first driver circuit 110 and the second driver circuit 120 is an example and is not limited to the sealing region 124 shown in FIG. 1. The region where the sealing region 124 overlaps the first driver circuit 110 and the second driver circuit 120 may be a region outside a region where a pixel circuit 182 (see FIG. 3) of the plurality of pixels 180 is arranged.

For example, the first driver circuit 110 is a source driver and includes a plurality of multiplexer circuits 111 for selecting a data signal. The multiplexer circuit 111 includes a plurality of analog switches (ASW) 112. The plurality of ASWs 112 are electrically connected between a plurality of data signal lines 131 and the plurality of data signal source lines 116, and has a function of electrically connecting the corresponding data signal line 131 and the data signal source line 116, respectively. For convenience of explanation, for example, the number of the ASWs 112 in the multiplexer circuit 111 shown in FIG. 2 is two. The number of the ASWs 112 included in the multiplexer circuit 111 may be greater than two.

For example, the second driver circuit 120 is a gate driver circuit. Furthermore, for example, the IC chip 400 supplies a control signal for driving the pixel circuit 182 to at least one of the first driver circuit 110 and the second driver circuit 120.

For example, each of the plurality of pixels 180 may correspond to a sub-pixel R, a sub-pixel G, and a sub-pixel B. The pixel 180 is the smallest unit constituting part of the images reproduced in the display region 122. Each of the pixels 180 includes one display element. In the example shown in FIG. 1, the display element is a liquid crystal element 170 (see FIG. 3). The color corresponding to the sub-pixel is determined by the characteristics of the liquid crystal element 170 or a color filter (not shown) arranged in the sub-pixel. In addition, the color filter may be arranged in the counter substrate 190 or may be arranged in the array substrate 100.

For example, the sub-pixel R may include a red color filter that emits red, the sub-pixel G may include a green color filter that emits green, and the sub-pixel B may include a blue color filter that emits blue.

A plurality of data signal lines including the data signal line 131 extends from first driver circuit 110 in the second direction D2 and is connected to the plurality of pixels 180 arranged in the second direction D2. A plurality of scan signal lines including a scan signal line 129 extends from the second driver circuit 120 in the first direction D1 and is connected to the plurality of pixels 180 arranged in the first direction D1.

For example, the common wiring 145 overlaps the peripheral region 121 and is arranged inside the outer periphery of the peripheral region 121. A common voltage is supplied to the common wiring 145 from an external device. For example, the common voltage may be a voltage between a voltage of the voltage amplitude of the positive side of the data signal and a voltage of the voltage amplitude of the negative side of the data signal, may be a voltage as a reference of the voltage amplitude, may be 0 V, or may be a ground voltage. The common wiring 145 may be electrically connected to a common electrode (not shown) formed in the counter substrate 190 via a plurality of connecting portions 143, and may be electrically connected to a common electrode 146 (see FIG. 3) using various wiring layers.

When the FPC 300 is connected to the FPC terminal part 150, the display device 10 is connected to an external device (not shown) connected to the FPC 300, and a signal from the external device is supplied to, for example, the IC chip 400, the first driver circuit 110, the second driver circuit 120, and each pixel 180. The display device 10 drives the pixel circuit 182 arranged in the display device 10 using a signal from the external device, and control signals generated by the IC chip 400, the first driver circuit 110, and the second driver circuit 120.

### [3. Configuration of Pixel Circuit 182 of Pixel 180]

A configuration of the pixel circuit 182 will be described with reference to FIG. 3. FIG. 3 is a schematic circuit diagram showing a configuration of the pixel circuit 182 of the pixel 180 in the display device 10. Configurations that are the same as or similar to those in FIG. 1 and FIG. 2 will be described as necessary.

For example, the pixel circuit 182 includes a transistor 160, the liquid crystal element 170, and a capacitance element 168. Although details will be described later, for example, a first electrode of the capacitance element 168 is a pixel electrode PTCO and a second electrode of the capacitance element 168 is grounded. Similar to the capacitance element 168, a first electrode of the liquid crystal element 170 is the pixel electrode PTCO and a second electrode of the liquid crystal element 170 is a common electrode CTCO. In addition, the first electrode and the second electrode of the capacitance element 168 are interchangeable. The first electrode and the second electrode of the liquid crystal element 170 are interchangeable. The second electrode of the liquid crystal element 170 is the common electrode 146. In addition, the second electrode of the capacitance element 168 may be the common electrode CTCO or the common electrode 146. The transistor 160 includes a first gate electrode 161, a first source electrode 163, and a first drain electrode 164. The first gate electrode 161 is connected to the scan signal line 129. The first source electrode 163 is connected to the data signal line 131. The first drain electrode 164 is connected to the first electrode of the capacitance element 168 and the first electrode of the liquid crystal element 170. Furthermore, in this specification and the like, for convenience of explanation, the first source electrode 163 may be referred to as a source electrode, and the first drain electrode 164 may be referred to as a drain electrode, and the function as the source and the function as the drain of each electrode may be replaced by the voltage supplied (applied) to the source electrode and the drain electrode of the transistor 160.

Any signal (voltage or current) is supplied to the pixel circuit 182 of each of the three sub-pixels of the display device 10, and the display device 10 can display an image. For example, the IC chip 400, the first driver circuit 110, the second driver circuit 120, and the external device supply a current or a voltage to each of the pixel electrodes and the common electrode 146 included in the pixel circuit 182, thereby changing the orientation status of liquid crystal molecules contained in the liquid crystal element 170. As a result, the display device 10 can display an image.

### [4. Configuration of Display Device 10]

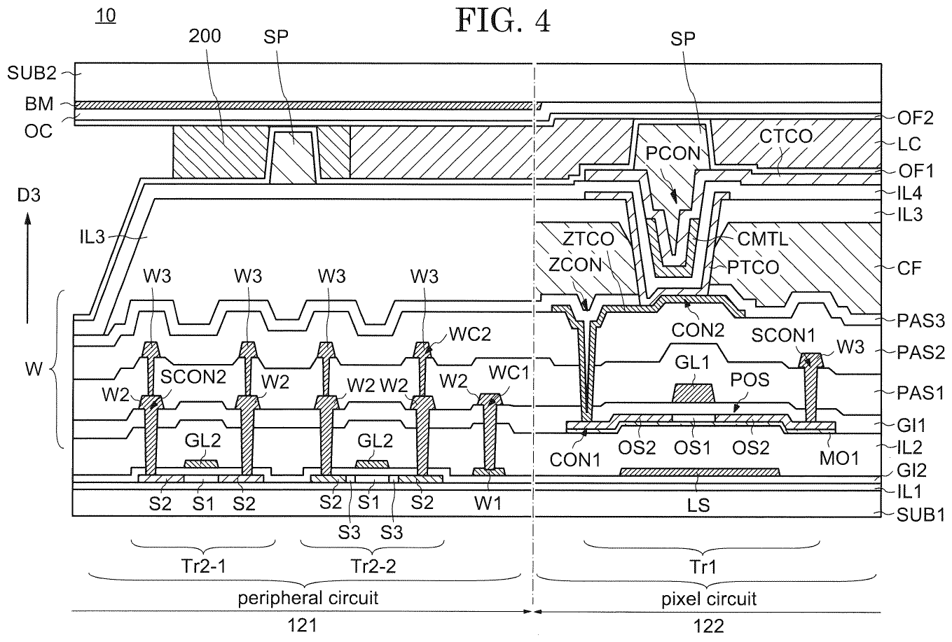

An outline of the display device 10 according to an embodiment of the present invention will be described with reference to FIG. 4 to FIG. 6. FIG. 4 is a cross-sectional view showing a configuration of the display device 10 according to an embodiment of the present invention. The cross-sectional view shown in FIG. 4 shows a transistor Tr2 in the peripheral region 121 and a transistor Tr1 in the pixel circuit 182 adjacent to each other. In practice, the pixel circuit 182 is included in the display region 122 and a peripheral circuit is included in the peripheral region 121. Therefore, it is needless to say that the pixel circuits and the peripheral circuit shown adjacently in FIG. 4 are arranged separately in the display device 10. In addition, the cross-sectional view shown in FIG. 4 shows the periphery of an opening of the pixel 180 and part of a transmission region (opening region) that contributes to displaying images. For example, the transistor Tr2 and the transistor Tr1 are thin film transistors. Configurations that are the same as or similar to those in FIG. 1 to FIG. 3 will be described as necessary.

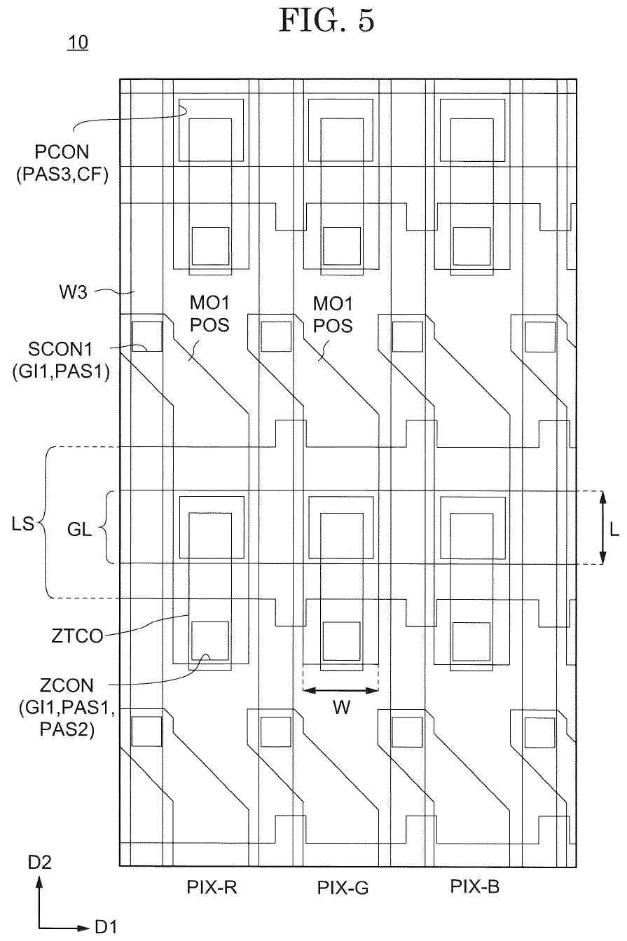

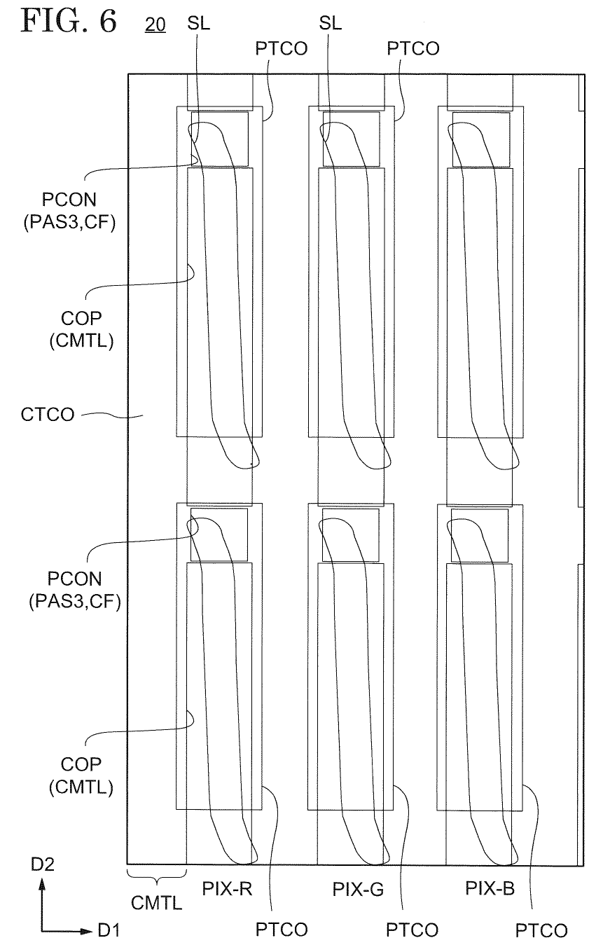

In addition, FIG. 5 and FIG. 6 are plan views showing a configuration of the pixels of the display device 10 according to an embodiment of the present invention. FIG. 5 shows a layout from a light shielding layer LS to a passivation layer PAS3, and FIG. 6 shows a layout from the passivation layer PAS3 to the common electrode CTCO.

As shown in FIG. 4, each layer included in the display device 10 is arranged above a substrate SUB1 (a third direction D3). The display device 10 includes the transistor Tr1, the transistor Tr2, a wiring group W including a plurality of wirings, a connecting electrode ZTCO, the pixel electrode PTCO, a common auxiliary electrode CMTL, and the common electrode CTCO. TCO is an abbreviation for Transparent Conductive Oxide. The transistor Tr1 is a transistor included in the pixel circuit 182 of the pixel 180 of the display device 10. The transistor Tr2 is a transistor included in the peripheral circuit such as the first driver circuit 110 or the second driver circuit 120. For example, the wiring group W includes a wiring W1, a wiring W2, and a wiring W3.

### [4-1. Configuration of Transistor Tr1]

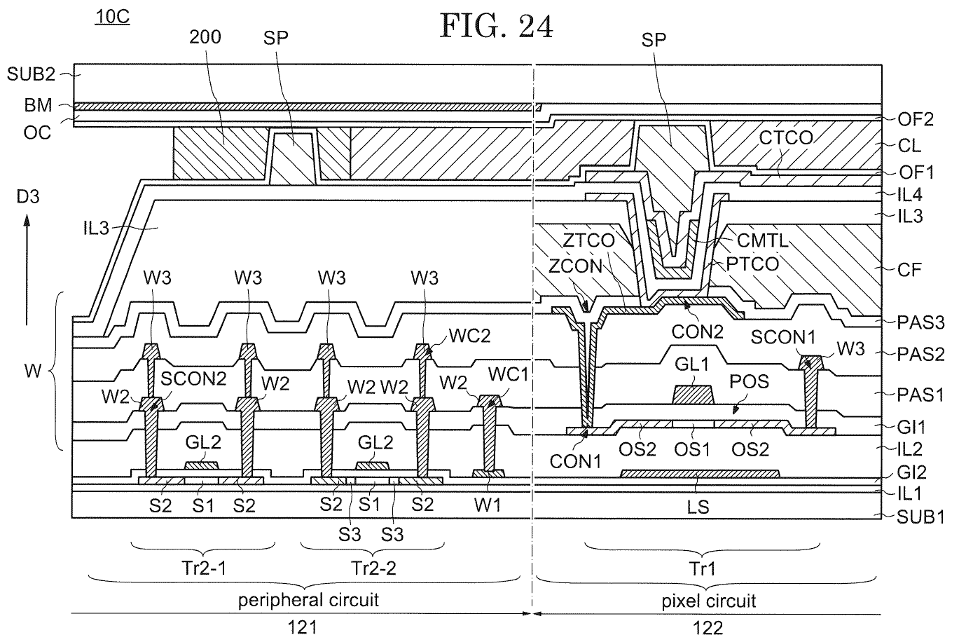

As shown in FIG. 4, the transistor Tr1 is arranged above the substrate SUB1. The transistor Tr1 includes at least an oxide semiconductor layer POS, a first gate insulating layer GI1, a gate wiring GL1 (also referred to as a gate electrode), a passivation layer PAS1, the wiring W3, a passivation layer PAS2, and the connecting electrode ZTCO (also referred to as a connecting electrode). The transistor Tr1 may further include the passivation layer PAS3 on the connecting electrode ZTCO. The transistor Tr1 may further include a second insulating layer IL2 and the light shielding layer LS between the oxide semiconductor layer POS and the substrate SUB1. In addition, the transistor Tr1 may further include a metal oxide layer MO1 containing aluminum as a main component, which is arranged in contact with the oxide semiconductor layer POS between the oxide semiconductor layer POS and the second insulating layer IL2. Although an example in which the metal oxide layer MO1 is arranged below the oxide semiconductor layer POS is described in FIG. 4, an embodiment of the present invention is not limited to this, and the oxide semiconductor layer POS may be in contact with the second insulating layer IL2 (see FIG. 24).

The gate wiring GL1 faces the oxide semiconductor layer POS. The first gate insulating layer GI1 is arranged between the oxide semiconductor layer POS and the gate wiring GL1. Although a top-gate transistor in which the oxide semiconductor layer POS is arranged closer to the substrate SUB1 than the gate wiring GL1 is exemplified as the transistor Tr1 in the present embodiment, a bottom-gate transistor in which the positional relationship between the gate wiring GL1 and the oxide semiconductor layer POS is reversed may be used. In addition, the configuration from the substrate SUB1 to the passivation layer PAS3 may be referred to as the semiconductor device.

The oxide semiconductor layer POS has a polycrystalline structure containing a plurality of crystal grains. Although details will be described later, the oxide semiconductor layer POS having a polycrystalline structure can be formed by using a Poly-OS (Poly-crystalline Oxide Semiconductor) technique. Hereinafter, the oxide semiconductor having a polycrystalline structure may be referred to as a Poly-OS.

Although details will be described later, the oxide semiconductor layer POS contains two or more metal elements including indium, and the ratio of indium in the two or more metal elements is 50% or more. Gallium (Ga), zinc (Zn), aluminum (Al), hafnium (Hf), yttrium (Y), zirconium (Zr), and lanthanoids are used as the metal element other than indium. However, it is sufficient that the oxide semiconductor layer POS contains the Poly-OS, and metal elements other than the above may be contained.

The oxide semiconductor layer POS includes a channel region OS1 and a low resistance region OS2. The channel region OS1 is an oxide semiconductor layer in a region that overlaps the gate wiring GL1 in a plan view. The channel region OS1 is switched between a conductive state and a non-conductive state depending on a voltage supplied to the gate wiring GL1. The low resistance region OS2 is a region having a lower resistance than the channel region OS1. The low resistance region OS2 functions as a source region or drain region. For example, the resistance of the low resistance region OS2 is reduced by ion-implantation of an impurity into the oxide semiconductor layer POS.

As shown in FIG. 5, the gate wiring GL1 is arranged along the first direction D1. A region of the gate wiring GL1 overlapping the oxide semiconductor layer POS is called a gate electrode. The oxide semiconductor layer POS is arranged so as to intersect with the gate wiring GL1. Furthermore, a region overlapping the gate wiring GL1 is the channel region OS1 in the oxide semiconductor layer POS. In FIG. 5, in the channel region OS1, a width of the gate wiring GL1 (length in the second direction D2) corresponds to a channel length L. In addition, the oxide semiconductor layer POS (length in the first direction D1) corresponds to the channel width W in the channel region OS1. In the present embodiment, a width (channel length L) of the gate wiring GL1 is 2.0 μm or less, preferably 1.5 μm or less.

The first gate insulating layer GI1 is arranged on the oxide semiconductor layer POS. The passivation layer PAS1 is arranged on the first gate insulating layer GI1. The wiring W3 is arranged on the passivation layer PAS1. As shown in FIG. 5, in a plan view, the wiring W3 is arranged along the second direction D2 and functions as a source wiring. The wiring W3 is connected to the low resistance region OS2 via an opening part SCON1 arranged in the first gate insulating layer GI1 and the passivation layers PAS1. The passivation layer PAS2 is arranged on the passivation layer PAS1 and the wiring W3. The connecting electrode ZTCO is arranged on the passivation layer PAS2. The connecting electrode ZTCO is connected to the low resistance region OS2 via an opening part ZCON arranged in the first gate insulating layer GI1 and the passivation layers PAS1 and PAS2. The connecting electrode ZTCO is in contact with the low resistance region OS2 at the bottom of the opening part ZCON. A region where the connecting electrode ZTCO contacts the low resistance region OS2 is called a contact region CON1.

The second insulating layer IL2 and the light shielding layer LS are arranged between the oxide semiconductor layer POS and the substrate SUB1. As shown in FIG. 5, in a plan view, the light shielding layer LS is arranged along the first direction D1 and is arranged in a region overlapping the gate wiring GL1. In addition, the light shielding layer LS is arranged so as to intersect the oxide semiconductor layer POS. In other words, in a plan view, the light shielding layer LS is arranged in a region overlapping the channel region OS1. The light shielding layer LS suppresses light incident from the substrate SUB1 side from reaching the channel region OS1. In the case where a conductive layer is used as the light shielding layer LS, a voltage is applied to the light shielding layer LS to control the channel region OS1. In the case where a voltage is supplied to the light shielding layer LS, the light shielding layer LS and the gate wiring GL1 may be electrically connected. In a plan view, the contact region CON1 is arranged in a region not overlapping the light shielding layer LS.

In the case where the display device 10 is required to have high-light transmittance, one of the source electrode and the drain electrode may be formed of a metal conductive layer and the other of the source electrode and the drain electrode may be formed of a transparent conductive layer. For example, when the transparent conductive layer such as an ITO is formed so as to be in contact with a silicon layer, a surface of the silicon layer is oxidized due to process gases and oxygen ions at the time of deposition of ITO. Since the oxide layer formed on the silicon layer has a high resistance, contact resistance between the silicon layer and transparent conductive layer increases. This leads to poor electrical contact between the silicon layer and the transparent conductive layer. On the other hand, even if the transparent conductive layer is formed to be in contact with the oxide semiconductor layer, the high resistance oxide layer as described above is not formed on the oxide semiconductor layer. Therefore, no defects occur in the electrical contacts between the oxide semiconductor layers and the transparent conductive layer.

In order to realize a high-definition display device 10, a width (channel length L) of the gate electrode of the transistor using the oxide semiconductor layer needs to be 2 μm or less. Considering the variation in the width of the gate electrode due to a photolithography process and etching in a manufacturing process of the display device 10, it is required to be able to be driven as a transistor even if it is 1.5 μm or less.

It is known that oxygen deficiencies occur in the oxide semiconductor due to processing damage such as etching. When hydrogen is trapped in the oxygen deficiencies, the resistance of the oxide semiconductor can be reduced to function as a conductor. On the other hand, supplying oxygen to the oxygen deficiencies to increase the resistance of the oxide semiconductor makes it possible to function as a semiconductor. That is, in order to operate as a transistor satisfactorily, in the channel region, it is preferable to increase the resistance of the oxide semiconductor by supplying oxygen to the oxygen deficiencies, and in the source region or drain region, it is preferable to reduce the resistance of the oxide semiconductor by supplying hydrogen to the oxygen deficiencies.

The characteristic of the transistor using the oxide semiconductor is greatly affected by hydrogen and oxygen contained in an insulating film arranged around the oxide semiconductor. When oxygen is excessively supplied to the oxide semiconductor, a defect level different from the oxygen deficiencies is formed due to the excessive oxygen, which leads to a decrease in the reliability of the transistor and a decrease in the field-effect mobility. Furthermore, if hydrogen is excessively supplied to the oxide semiconductor and hydrogen is supplied to the channel region, the transistor is depleted, and the transistor does not operate.

Therefore, in order to miniaturize the transistor using the oxide semiconductor, oxygen and hydrogen need to be appropriately supplied to the channel region OS1 having a channel length of 2.0 μm or less and the low resistance region OS2.

In an embodiment of the present invention, hydrogen is appropriately supplied to the oxide semiconductor layer POS, thereby reducing the resistance of the low resistance region OS2 functioning as the source region and the drain region and suppressing the diffusion of hydrogen to the channel region OS1.

In the present embodiment, a silicon nitride layer is used as the passivation layers PAS1 to PAS3. The silicon nitride layer contains more hydrogen than silicon oxide. Hydrogen contained in the silicon nitride layer diffuses when heat exceeding 250° C. is applied. Therefore, the silicon nitride layer is formed at 150° C. or higher and 250° C. or lower as the passivation layers PAS1 to PAS3. As a result, it is possible to suppress a large amount of hydrogen contained in the silicon nitride layer from diffusing, and it is possible to suppress hydrogen from being excessively supplied to the low resistance region OS2. Therefore, it is possible to suppress the transistor Tr1 from being depleted. The configuration of the passivation layers PAS1 to PAS3 will be described later.

### [4-2. Configuration of Transistor Tr2]

The transistor Tr2 has a p-type transistor Tr2-1 and an n-type transistor Tr2-2. When the transistor Tr2 is not distinguished, the transistor included in the peripheral region 121 is expressed as the transistor Tr2. When the transistor Tr2 is distinguished, the transistor Tr2 is expressed as the p-type transistor Tr2-1, the n-type transistor Tr2-2, or the like.

Each of the p-type transistor Tr2-1 and the n-type transistor Tr2-2 has a gate electrode GL2, a second gate insulating layer GI2, and a semiconductor layer S. The gate electrode GL2 faces the semiconductor layer S. The second gate insulating layer GI2 is arranged between the semiconductor layer S and the gate electrode GL2. For example, the transistor Tr2 of the display device 10 is a top-gate transistor in which the gate electrode GL2 is arranged above the semiconductor layer S. The transistor Tr2 may be a bottom-gate transistor in which the positional relationship between the semiconductor layer S and the gate electrode GL2 is reversed.

A first insulating layer IL1 is arranged on the substrate SUB1. The first insulating layer IL1 functions as a base layer. Arranging the first insulating layer IL1 makes it possible to suppress the entry of an impurity from the substrate SUB1 into the semiconductor layer S.

The semiconductor region S of the p-type transistor Tr2-1 includes semiconductor regions S1 and S2. The semiconductor region S of the n-type transistor Tr2-2 includes the semiconductor regions S1, S2, and S3. The semiconductor region S1 is a semiconductor in a region overlapping the gate electrode GL2 in a plan view. The semiconductor region S1 functions as a channel region of the transistor Tr2-1. The semiconductor region S2 functions as a conductor. The semiconductor region S3 functions as a conductor having higher resistance than the semiconductor region S2. The semiconductor region S3 suppresses hot carrier degradation by attenuating hot carriers entering toward the semiconductor region S1.

The second insulating layer IL2 and the first gate insulating layer GI1 are arranged on the gate electrode GL2. The wiring W2 is arranged on these insulating layers. The wiring W2 functions as a source electrode and a drain electrode of the transistor Tr2. The wiring W2 is connected to the semiconductor region S via an opening part SCON2 arranged in the second insulating layer IL2, the first gate insulating layer GI1, and the second gate insulating layer GI2. In addition, the wiring W2 is connected to the wiring W1 via an opening WC1 arranged in the second insulating layer IL2 and the first gate insulating layer GI1. The passivation layer PAS1 is arranged on the wiring W2. The wiring W3 is arranged on the passivation layer PAS1. The wiring W3 is connected to the wiring W2 via an opening WC2 arranged in the passivation layer PAS1.

The gate electrode GL2 is formed in the same layers as the wiring W1 and the light shielding layer LS. The wiring W2 is formed in the same layers as the gate wiring GL1. The same layer means that a single layer is patterned to form a plurality of members.

### [4-3. Other Configurations of Display Device]

Next, a layer structure arranged on the transistor Tr1 and the transistor Tr2 will be described. In the display region 122, a color filter CF is arranged on the passivation layer PAS3. The positional deviation between the color filter CF and the pixel circuit can be suppressed by arranging the color filter CF on the substrate SUB1 side. In addition, a third insulating layer IL3 is arranged on the color filter CF and the passivation layer PAS3. Since the color filter CF is not arranged in the peripheral region 121, the third insulating layer IL3 is arranged on the passivation layer PAS3. The third insulating layer IL3 functions as a planarization film.

The pixel electrode PTCO is arranged on the third insulating layer IL3 in the display region 122. The pixel electrode PTCO is connected to the connecting electrode ZTCO via an opening part PCON arranged in the third insulating layer IL3. As shown in FIG. 5 and FIG. 6, the pixel electrode PTCO overlaps the gate wiring GL1, the oxide semiconductor layer POS, and the connecting electrode ZTCO between two adjacent wirings W3. The pixel electrode PTCO contacts the connecting electrode ZTCO at the opening part PCON overlapping the gate wiring GL1.

A fourth insulating layer IL4 is arranged in the display region 122 and the peripheral region 121. In the display region 122, the fourth insulating layer IL4 is arranged so as to cover the pixel electrode PTCO and the third insulating layer IL3. Furthermore, in the peripheral region 121, the fourth insulating layer IL4 is arranged on the third insulating layer IL3. In addition, the fourth insulating layer IL4 is in contact with the third insulating layer IL3 at an end portion of the peripheral region 121 (end portion of the substrate SUB1). As a result, moisture contained in the third insulating layer IL3 can be sealed.

The common auxiliary electrode CMTL and the common electrode CTCO are arranged on the fourth insulating layer IL4 in the display region 122. As shown in FIG. 6, the common auxiliary electrode CMTL and the common electrode CTCO are arranged in a grid pattern so as to overlap the gate wiring GL and the wiring W3. That is, the common auxiliary electrode CMTL is arranged in common to a plurality of pixels. In other words, the common auxiliary electrode CMTL has an opening OP. The opening OP is arranged to expose the pixel electrode PTCO. The pattern of the opening OP is arranged inside the pattern of the pixel electrode PTCO. In addition, a region where the opening OP is arranged corresponds to the opening part of an opening of the pixel. That is, the opening part ZCON (the first contact region CON1) is included in the opening part of the pixel. The opening part of the pixel means a region that allows a user to see the light from the pixel. For example, a region that is shielded by the metal layer and is not visible to the user is not included in the opening part of the pixel. That is, the opening part of the pixel may be referred to as a “translucent region”. Furthermore, a region extending along the direction D1 of the common auxiliary electrode CMTL overlaps the opening part PCON. In the display region 122, the common auxiliary electrode CMTL also functions as a black matrix. In addition, the common auxiliary electrode CMTL and the common electrode CTCO are arranged in the opening part PCON. Although the case where the common electrode CTCO is arranged on the common auxiliary electrode CMTL is described in FIG. 4, the common auxiliary electrode CMTL may be arranged on the common electrode CTCO. Here, as shown in FIG. 4, the pixel electrode PTCO overlaps the common electrode CTCO via the fourth insulating layer IL4. A region where the pixel electrode PTCO overlaps the common electrode CTCO via the fourth insulating layer IL4 functions as a storage capacitor.

A spacer SP is arranged on the common electrode CTCO to fill the opening part PCON. The spacer SP protrudes toward a counter substrate SUB2. Due to the spacer SP, the spacer SP of a liquid crystal layer LC is arranged not only in the display region 122 but also in the peripheral region 121. In the display region 122 and the peripheral region 121, an alignment film OF1 is arranged on the third insulating layer IL3, the common electrode CTCO, and the spacer SP.

In the peripheral region 121, a black matrix BM is arranged on the counter substrate SUB2. An overcoat layer OC is arranged in the peripheral region 121 and the display region 122. An alignment film OF2 is arranged so as to cover the overcoat layer OC. The substrate SUB1 and the counter substrate SUB2 are arranged such that the alignment film OF1 and the alignment film OF2 face each other, and are bonded to each other by the seal part 200 arranged in the peripheral region 121. The liquid crystal layer LC is arranged in a region surrounded by the seal part 200.

### [5. Method of Manufacturing Display Device 10]

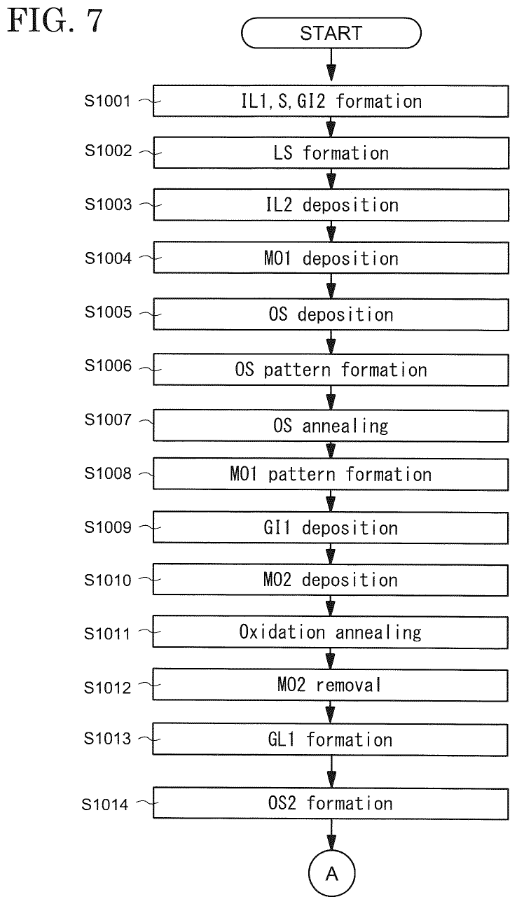

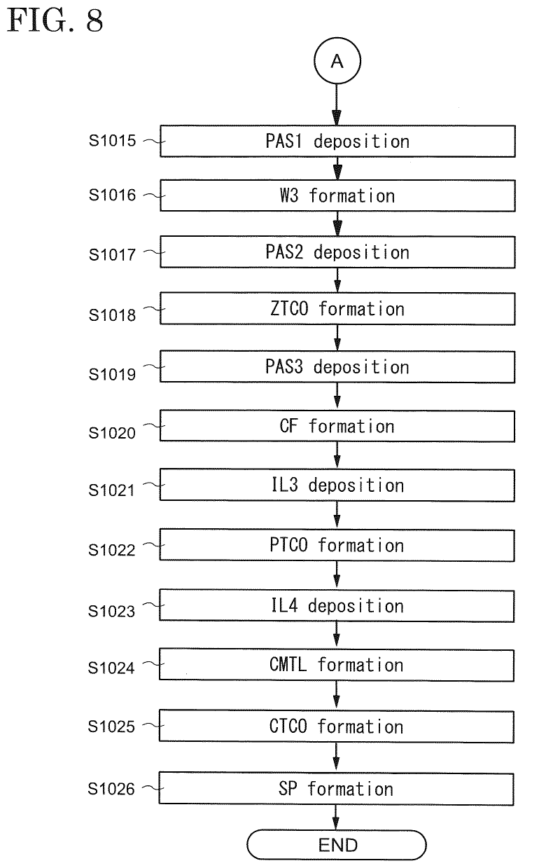

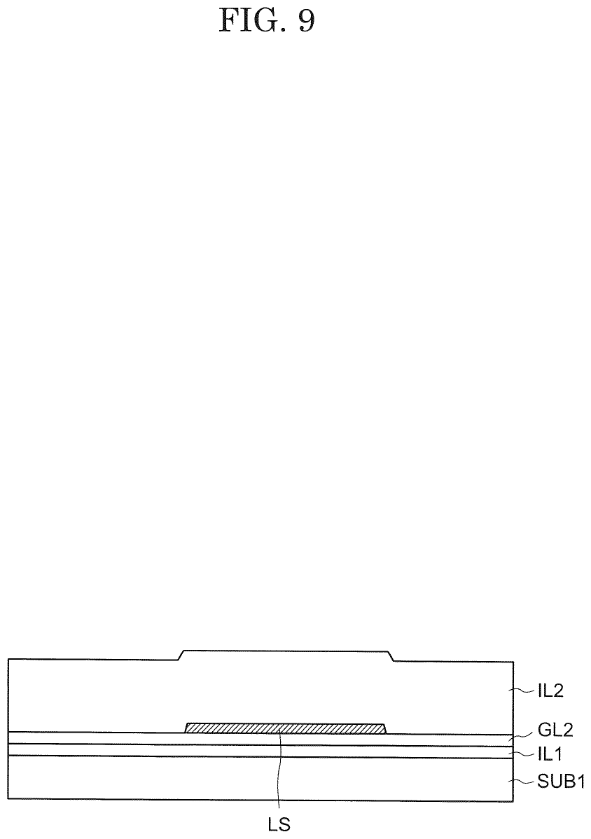

A method of manufacturing the display device 10 according to an embodiment of the present invention will be described. FIG. 7 and FIG. 8 are sequential diagrams illustrating a method of manufacturing the display device 10 according to an embodiment of the present invention. FIG. 9 to FIG. 17 are cross-sectional views illustrating a manufacturing method in the display device 10 according to an embodiment of the present invention.

First, the first insulating layer IL1, a semiconductor region S, and the second gate insulating layer GI2 are formed on the substrate SUB1 (see step S1001 shown in FIG. 7 and FIG. 9).

A rigid substrate having light transmittance, such as a glass substrate, a quartz substrate, and a sapphire substrate, is used as the substrate SUB1. In the case where the substrate SUB1 needs to have flexibility, a substrate containing an organic resin such as a polyimide substrate, an acryl substrate, a siloxane substrate, or a fluororesin substrate is used. In the case where the substrate containing an organic resin is used as the substrate SUB1, in order to improve the heat resistance of the substrate SUB1, an impurity element may be introduced into the organic resin.

The first insulating layer IL1 is formed by a CVD (Chemical Vapor Deposition) method or a sputtering method. For example, an inorganic insulating material such as silicon oxide (SiOₓ), silicon oxynitride (SiOₓN_{y}), silicon nitride (SiNₓ), or silicon nitride oxide (SiNₓO_{y}) is used as the first insulating layer IL1. The SiOₓN_{y} is a silicon compound containing a smaller proportion (x>y) of nitrogen (N) than oxygen (O). SiNₓO_{y} is a silicon compound containing a smaller proportion (x>y) of oxygen than nitrogen. The first insulating layer IL1 may be a single layer structure using the inorganic insulating material described above, or may be a stacked structure.

In addition, polysilicon is used as the semiconductor region S. Furthermore, the same deposition method and inorganic insulating material as those of the first insulating layer IL1 are used as the second gate insulating layer GI2.

Next, the light shielding layer LS is formed on the gate insulating layer GI2 (see step S1002 shown in FIG. 7 and see FIG. 9).

For example, the light shielding layer LS is formed by processing a conductive layer formed by the sputtering method. A typical metal material is used as the light shielding layer LS. For example, aluminum (Al), titanium (Ti), chromium (Cr), cobalt (Co), nickel (Ni), molybdenum (Mo), hafnium (Hf), tantalum (Ta), tungsten (W), bismuth (Bi), silver (Ag), copper (Cu), and an alloy or compound thereof is used as the light shielding layer LS. In addition, the light shielding layer LS may be a single layer structure using the above-described materials, or may be a stacked structure.

Next, the second insulating layer IL2 is formed on the light shielding layer LS (see step S1003 shown in FIG. 7 and see FIG. 9). The same deposition method and inorganic insulating material as those of the first insulating layer IL1 are used as the second insulating layer IL2.

In addition, the second insulating layer IL2 may be a single layer structure using the inorganic insulating material described above, or may be a stacked structure. In the case where the second insulating layer IL2 is a stacked structure, it is preferable that an insulating material containing nitrogen and an insulating material containing oxygen are formed in this order from the substrate SUB1. For example, an impurity that diffuses from the substrate SUB1 toward the oxide semiconductor layer POS can be blocked by using the insulating material containing nitrogen. In addition, oxygen can be released by heat treatment by using the insulating material containing oxygen. For example, the temperature of the heat treatment in which the insulating material containing oxygen releases oxygen is 600° C. or lower, 500° C. or lower, 450° C. or lower, or 400° C. or lower. That is, for example, the insulating material containing oxygen releases oxygen at a heat treatment temperature performed in a manufacturing process of the display device when a glass substrate is used as the substrate SUB1. In the present embodiment, for example, silicon nitride is formed as the insulating material containing nitrogen. In addition, for example, silicon oxide is formed as the insulating material containing oxygen.

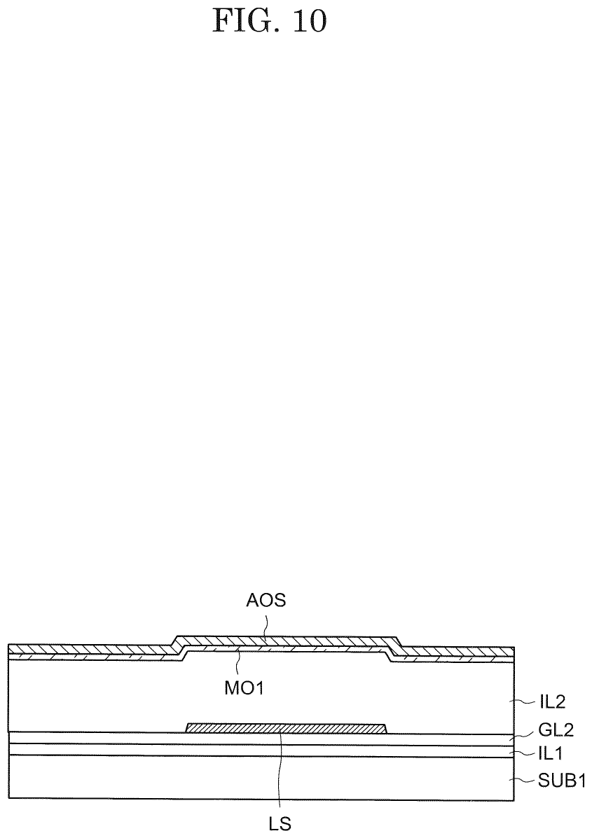

Next, the metal oxide layer MO1 containing aluminum as a main component is formed on the second insulating layer IL2 (see step S1004 shown in FIG. 7 and see FIG. 10).

The metal oxide layer MO1 is formed by the sputtering method. For example, an inorganic insulating material such as aluminum oxide (AlOₓ), aluminum oxynitride (AlOₓN_{y}), aluminum nitride oxide (AlNₓO_{y}), or aluminum nitride (AlNₓ) is used as the metal oxide layer MO1 containing aluminum as a main component. AlOₓN_{y} is an aluminum compound containing a smaller proportion (x>y) of nitrogen (N) than oxygen (O). AlNₓO_{y} is an aluminium compound containing a smaller proportion (x>y) of oxygen than nitrogen.

The “metal oxide layer containing aluminum as a main component” means that the proportion of aluminum contained in the metal oxide layer MO1 is 1% or more of the total amount of the metal oxide layer MO1. The proportion of the aluminum contained in the metal oxide layer MO1 may be 5% or more and 70% or less, 10% or more and 60% or less, or 30% or more and 50% or less of the total amount of the metal oxide layer MO1. The ratio may be a mass ratio or a weight ratio.

For example, a thickness of the metal oxide layer MO1 is 1 nm or more and 10 nm or less, 1 nm or more and 4 nm or less, or 1 nm or more and 3 nm or less. In the present embodiment, aluminum oxide is used as the metal oxide layer MO1. Aluminum oxide has a high barrier property against gas.

Next, an amorphous oxide semiconductor layer AOS is formed on the metal oxide layer MO1 (see step S1005 shown in FIG. 7 and FIG. 10).

The oxide semiconductor layer AOS is deposited by the sputtering method or an atomic layer deposition method (ALD). For example, a thickness of the oxide semiconductor layer AOS is 5 nm or more and 50 nm or less, preferably 10 nm or more and 40 nm or less, and more preferably 10 nm or more and 30 nm or less.

A metal oxide having semiconductor properties can be used as the oxide semiconductor layer AOS. For example, an oxide semiconductor containing two or more metals including indium (In) is used as the oxide semiconductor layer AOS. In addition, the proportion of indium in the two or more metals is 50% or more. Gallium (Ga), zinc (Zn), aluminum (Al), hafnium (Hf), yttrium (Y), zirconium (Zr), or lanthanoids are used as the oxide semiconductor layer AOS in addition to indium. Elements other than those described above may be used as the oxide semiconductor layer AOS. In the present embodiment, a metal oxide containing indium (In) and gallium (Ga) is used as the oxide semiconductor layer AOS.

In the case where the oxide semiconductor layer is crystallized by an OS annealing treatment described later, the oxide semiconductor layer AOS after the deposition and before the OS annealing treatment is preferably amorphous (a state in which the oxide semiconductor has little crystalline component). That is, it is preferable that the oxide semiconductor layer AOS immediately after the deposition does not crystallize as much as possible in the deposition method of the oxide semiconductor layer AOS. For example, in the case where the oxide semiconductor layer AOS is deposited by the sputtering method, the oxide semiconductor layer AOS is deposited while controlling the temperature of an object to be film-formed (the substrate SUB1 and a structure formed thereon).

When the deposition is performed on the object to be film-formed by the sputtering method, ions generated in the plasma and atoms recoiled by a sputtering target collide with the object to be film-formed, so that the temperature of the object to be film-formed increases with the deposition processing. When the temperature of the object to be film-formed during the deposition processing increases, microcrystals are contained in the oxide semiconductor layer AOS immediately after the deposition, and crystallization by the subsequent OS annealing treatment is inhibited. In order to control the temperature of the object to be film-formed as described above, for example, the deposition may be performed while cooling the object to be film-formed. For example, the object to be film-formed may be cooled from the surface opposite to the surface to be film-formed so that the temperature of the surface to be film-formed of the object to be film-formed (hereinafter, referred to as “deposition temperature”) is 100° C. or lower, 70° C. or lower, 50° C. or lower, or 30° C. or lower. As described above, depositing the oxide semiconductor layer AOS while cooling the object to be film-formed makes it possible to form the oxide semiconductor layer AOS with few crystalline components immediately after the deposition.

Next, a pattern of the oxide semiconductor layer AOS is formed (see step S1006 shown in FIG. 7). Although not shown, a resist mask is formed on the oxide semiconductor layer AOS, and the oxide semiconductor layer AOS is etched using the resist mask. Wet etching may be used, or dry etching may be used as the etching of the oxide semiconductor layer AOS. Etching may be performed using an acidic etchant as the wet etching. For example, oxalic acid or hydrofluoric acid may be used as the etchant.

The oxide semiconductor layer AOS is preferably patterned before the OS annealing. When the oxide semiconductor layer AOS is crystallized by the OS annealing treatment, it tends to be difficult to etch. In addition, even if the oxide semiconductor layer AOS is damaged by the etching, the damage can be repaired by the OS annealing treatment, which is preferable.

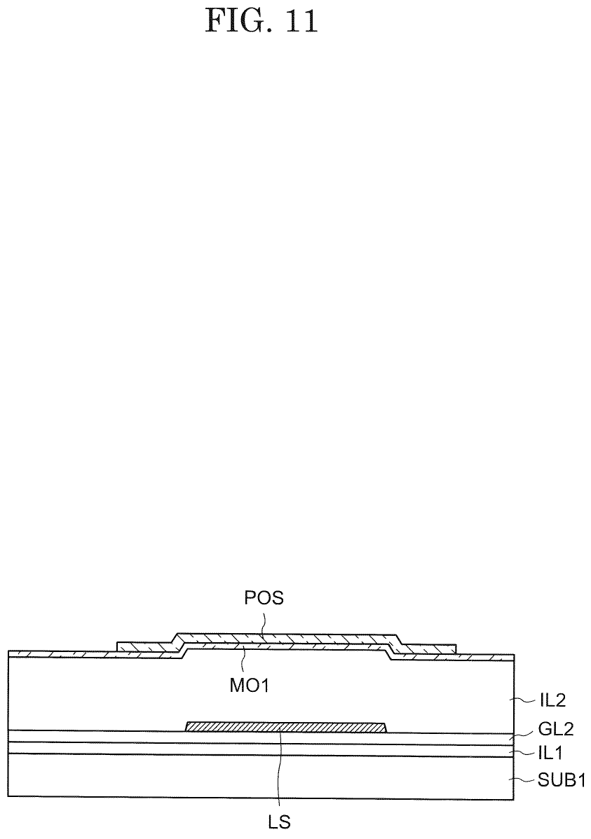

After the pattern of the oxide semiconductor layer AOS is formed, the oxide semiconductor layer AOS is subjected to a heat treatment (OS annealing treatment) (see step S1007 shown in FIG. 7 and FIG. 11). In the OS annealing treatment, the oxide semiconductor layer AOS is held at a predetermined reached temperature for a predetermined period of time. The predetermined reached temperature is 300° C. or higher and 500° C. or lower, preferably 350° C. or higher and 450° C. or lower. In addition, the holding time at the reached temperature is 15 minutes or more and 120 minutes or less, preferably 30 minutes or more and 60 minutes or less. By performing the OS annealing treatment, the oxide semiconductor layer AOS is crystallized, and the oxide semiconductor layer POS having a polycrystalline structure is formed.

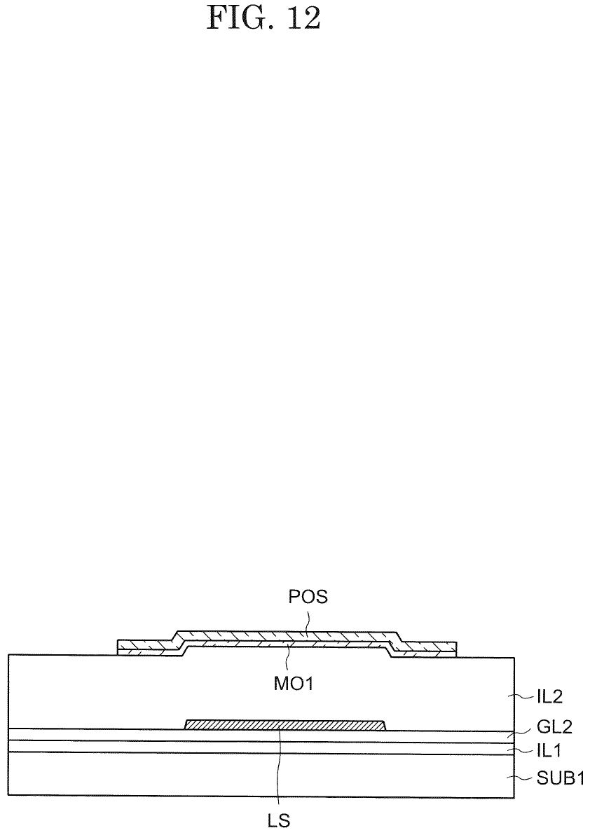

Next, a pattern of the metal oxide layer MO1 is formed using the oxide semiconductor layer POS as a mask (see step S1008 shown in FIG. 7 and see FIG. 12). The metal oxide layer MO1 is etched using the crystallized oxide semiconductor layer POS as a mask. Wet etching may be used, or dry etching may be used as the etching of the metal oxide layer MO1. For example, dilute hydrofluoric acid (DHF) is used as the wet etching. The crystallized oxide semiconductor layer POS has etching resistance to dilute hydrofluoric acid as compared with the amorphous oxide semiconductor layer AOS. Therefore, the metal oxide layer MO1 can be etched using the oxide semiconductor layer POS as a mask. As a result, the photolithography process can be omitted.

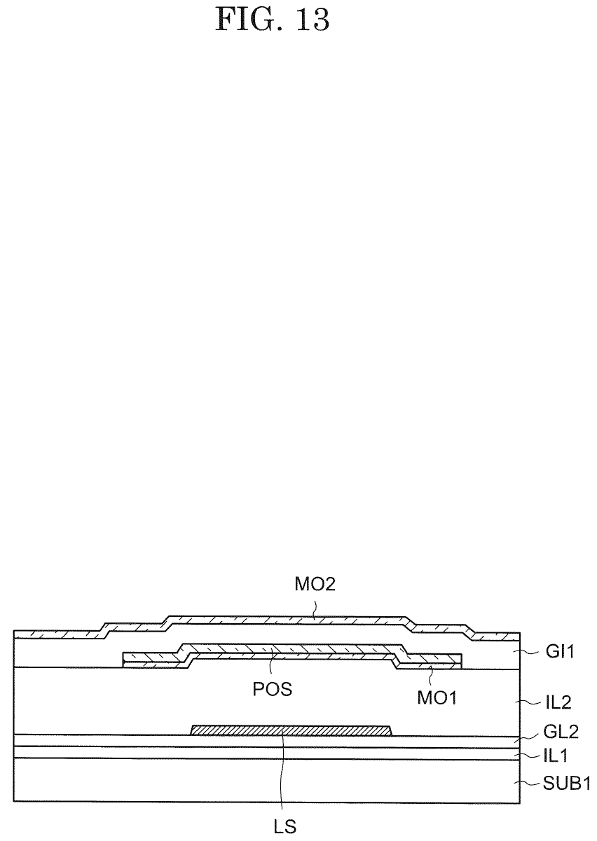

Next, the first gate insulating layer GI1 is formed on the oxide semiconductor layer POS (see step S1009 shown in FIG. 7 and see FIG. 13).

The deposition method of the first gate insulating layer GI1 and the insulating material may refer to the description of the second insulating layer IL2. For example, a thickness of the first gate insulating layer GI1 is 50 nm or more and 300 nm or less, preferably 60 nm or more and 200 nm or less, and more preferably 70 nm or more and 150 nm or less.

An insulating material containing oxygen is preferably used as the first gate insulating layer GI1. In addition, an insulating layer with few defects is preferably used as the first gate insulating layer GI1. For example, in the case where the composition ratio of oxygen in the second GI1 is compared with the composition ratio of oxygen in an insulating layer (hereinafter referred to as “another insulating layer”), the composition ratio of oxygen in the first gate insulating layer GI1 is closer to the stoichiometric ratio than the composition ratio of the oxygen in the other insulating layer. For example, in the case where silicon oxide (SiOₓ) is used for each of the first gate insulating layer GI1 and the second gate insulating layer GI2, the composition ratio of oxygen in the silicon oxide used as the first gate insulating layer GI1 is closer to the stoichiometric ratio of silicon oxide than the composition ratio of oxygen in the silicon oxide used as the second gate insulating layer GI2. For example, a layer in which no defects are observed when evaluating by an electron-spin resonance method (ESR) may be used as the first gate insulating layer GI1.

In order to form the insulating layer with few defects as the first gate insulating layer GI1, the first gate insulating layer GI1 may be deposited at a deposition temperature of 350° C. or higher. In addition, after the first gate insulating layer GI1 is formed, an oxygen-implanting process may be performed on a part of the first gate insulating layer GI1. In the present embodiment, silicon oxide is formed at a deposition temperature of 350° C. or higher in order to form an insulating layer with few defects as the first gate insulating layer GI1.

Next, a metal oxide layer MO2 containing aluminum as a main component is formed on the first gate insulating layer GI1 (see step S1010 shown in FIG. 7 and see FIG. 13).

For a description of the deposition method of the metal oxide layer MO2 and the insulating material, refer to the description of the metal oxide layer MO1. Oxygen is implanted into the first gate insulating layer GI1 by the deposition of the metal oxide layer MO2. For example, a thickness of the metal oxide layer MO2 is 5 nm or more and 100 nm or less, 5 nm or more and 50 nm or less, 5 nm or more and 30 nm or less, or 7 nm or more and 15 nm or less. In the present embodiment, aluminum oxide is used as the metal oxide layer MO2. Aluminum oxide has a high barrier property against gas. In the present embodiment, the aluminum oxide used as the metal oxide layer MO2 suppresses the oxygen implanted into the first gate insulating layer GI1 from diffusing outward during the deposition of the metal oxide layer MO2.

For example, in the case where the metal oxide layer MO2 is formed by the sputtering method, the process gas used in the sputtering remains in the film of the first gate insulating layer GI1. For example, in the case where Ar is used as the process gas for sputtering, Ar may remain in the film of the first gate insulating layer GI1. The remaining Ar can be detected by a SIMS (Secondary Ion Mass Spectrometry) analysis on the first gate insulating layer GI1.

A heat treatment (oxidation annealing treatment) for supplying oxygen to the oxide semiconductor layer POS is performed while the first gate insulating layer GI1 is formed on the oxide semiconductor layer POS and the metal oxide layer MO2 is formed on the first gate insulating layer GI1 (see step S1011 shown in FIG. 7).

Many oxygen deficiencies occur on the upper surface and side surface of the oxide semiconductor layer POS during the process from the deposition of the oxide semiconductor layer POS to the deposition of the first gate insulating layer GI1 on the oxide semiconductor layer POS. Therefore, the number of oxygen deficiencies formed near the upper surface of the oxide semiconductor layer POS is greater than the number of oxygen deficiencies formed near the lower surface of the oxide semiconductor layer POS. That is, the oxygen deficiencies in the oxide semiconductor layer POS are not uniformly present in the thickness direction of the oxide semiconductor layer POS, but are non-uniformly distributed in the thickness direction of the oxide semiconductor layer POS. Specifically, the number of oxygen deficiencies in the oxide semiconductor layer POS is fewer on the lower surface side of the oxide semiconductor layer POS but is greater on the upper surface side of the oxide semiconductor layer POS.

In the case where an oxygen supply process is uniformly performed on the oxide semiconductor layer POS having the oxygen deficiency distribution as described above, oxygen is excessively supplied to the lower surface side of the oxide semiconductor layer POS when oxygen required for repairing the oxygen deficiencies formed on the upper surface side of the oxide semiconductor layer POS is supplied. This forms a defect level different from the oxygen deficiencies on the lower surface side by the excess oxygen. As a result, phenomenon such as variation in properties in the reliability test or a decrease in the field-effect mobility occurs. Therefore, in order to suppress such a phenomenon, oxygen needs to be supplied to the upper surface side of the oxide semiconductor layer POS while suppressing the oxygen supply to the lower surface side of the oxide semiconductor layer POS.

Oxidation annealing is performed in a state where the metal oxide layer MO1 is arranged below the oxide semiconductor layer POS and the oxide semiconductor layer MO2 is arranged on the oxide semiconductor layer POS. As a result, in the above-described oxidation annealing treatment, the oxygen implanted in the first gate insulating layer GI1 is blocked by the metal oxide layer MO2, so that the oxygen is suppressed from being released into the atmosphere. In addition, the oxygen released from the second insulating layer IL2 is supplied to the upper surface and the side surface of the oxide semiconductor layer POS. Furthermore, the metal oxide layer MO1 can suppress excessive oxygen from being supplied below the oxide semiconductor layer POS. As a result, the oxygen is efficiently supplied to the oxide semiconductor layer POS, thereby repairing the oxygen deficiencies.

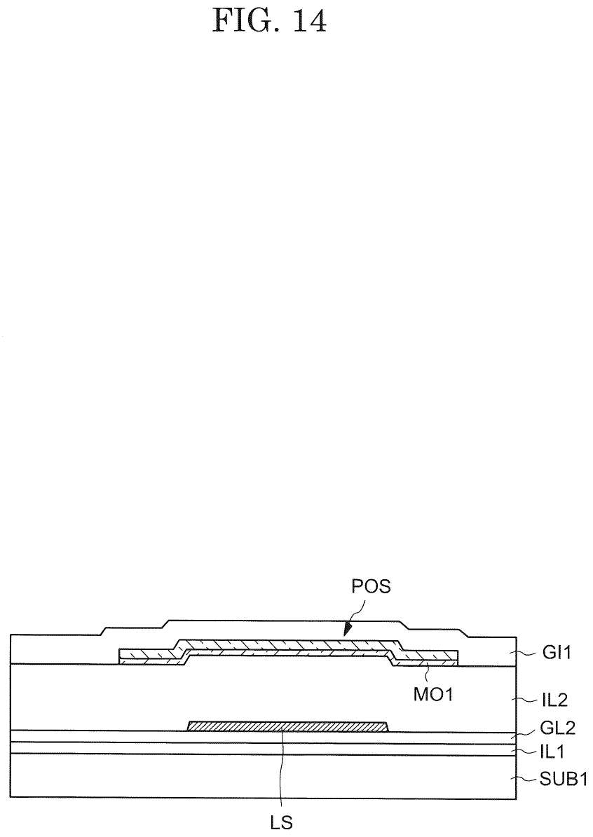

Next, after the oxidation annealing treatment, the metal oxide layer MO2 is etched (removed) (see step S1012 shown in FIG. 7 and see FIG. 14). Wet etching may be used, or dry etching may be used as the etching of the metal oxide layer MO2. For example, dilute hydrofluoric acid (DHF) is used as the wet etching. The metal oxide layer MO2 formed on the entire surface is removed by the etching. In other words, the metal oxide layer MO2 is removed without using a mask. In other words, the etching removes all of the metal oxide layer MO2 in a region overlapping the oxide semiconductor layer POS formed in a certain pattern at least in a plan view.

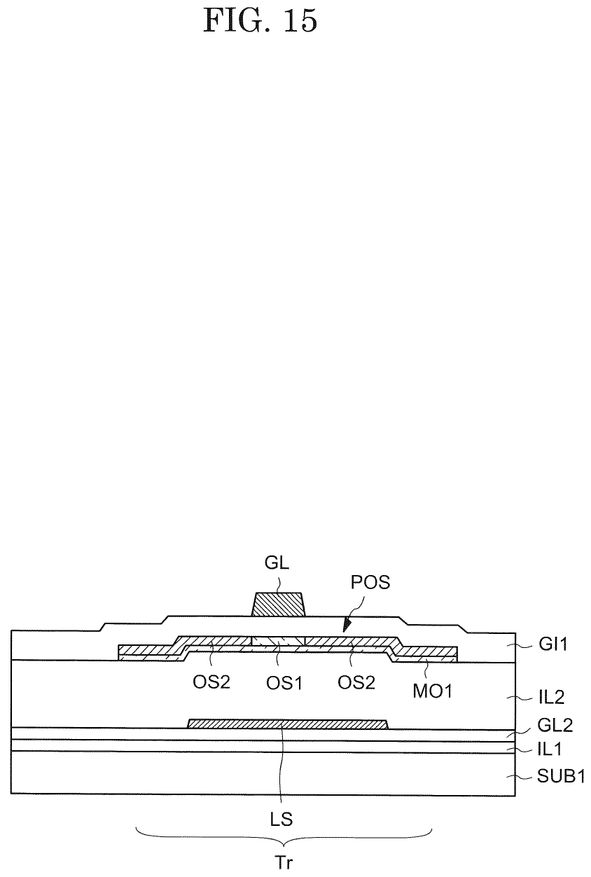

Next, the gate wiring GL1 is formed on the first gate insulating layer GI1 (see step S1013 shown in FIG. 7 and see FIG. 15). The deposition method of the wiring GL and the conductive material may refer to the description of the light shielding layer LS.

Next, an impurity is added to the oxide semiconductor layer POS using the gate wiring GL1 as a mask (see step S1014 shown in FIG. 7 and see FIG. 15). Although the case where the impurity is added by ion implantation is described in the present embodiment, it may be performed by an ion doping method.

Specifically, an impurity element is added to the oxide semiconductor layer POS through the first gate insulating layer GI1 by ion implantation, thereby forming the low resistance region OS2. In addition, the region overlapping the gate wiring GL1 becomes the channel region OS1 in the oxide semiconductor layer POS. For example, argon (Ar), phosphorus (P), or boron (B) may be used as the impurity element. Furthermore, in the case where boron (B) is added by the ion-implantation method, the acceleration energy may be set to 20 keV or more and 40 keV or less, and the implantation amount of boron (B) may be set to 1×10¹⁴ cm⁻² or more and 1×10¹⁶ cm⁻² or less.

The concentration of the impurity element contained in the low resistance region OS2 is preferably 1×10¹⁸ cm⁻³ or more and 1×10²¹ cm⁻³ or less as measured by the SIMS spectrometry (secondary ion-mass spectrometry). In addition, in the case where the low resistance region OS2 contains 1×10¹⁸ cm⁻³ or more and 1×10²¹ cm⁻³ or less, it is presumed that the impurity element is intentionally added by the ion-implantation method or the doping method.

When the impurity element is ion-implanted into the oxide semiconductor layer POS, oxygen deficiencies are formed in the low resistance region OS2, and defects are also formed in the metal oxide layer MO1 and the second insulating layer IL2 arranged below the low resistance region OS2. In a subsequent process, the resistance of the low resistance region OS2 can be further reduced by supplying hydrogen to the oxygen deficiencies. For example, using a silicon nitride layer as a passivation layer can be the method of supplying hydrogen to the oxygen deficiencies. Since the silicon nitride layer contains a large amount of hydrogen at the time of deposition, the resistance of the low resistance region OS2 can be reduced by trapping the hydrogen contained in the silicon nitride layer in the oxygen deficiencies of the low resistance region OS2. In addition, hydrogen is trapped in the defects formed by ion-implantation in the metal oxide layer MO1 and the second insulating layer IL2, thereby suppressing hydrogen from being supplied to the channel region OS1 more than necessary. However, when a large amount of hydrogen is diffused when the silicon nitride layer is formed, the oxygen deficiencies of the low resistance region OS2 and the defects of the metal oxide layer MO1 and the second insulating layer IL2 cannot trap all of the hydrogen. If hydrogen is supplied to the oxygen deficiencies of the low resistance region OS2, hydrogen is supplied from the low resistance region OS2 to the channel region OS1, and the transistor will be depleted.

Silicon oxide may be used in combination as a passivation layer so that hydrogen is not excessively supplied to the low resistance region OS2, but dust (particles) may be generated by reactive gas when the silicon oxide film is formed. Since it is difficult to remove the dust and it is an obstacle to the subsequent manufacturing process, it is less desirable to use a thick silicon oxide as the passivation layer.

Therefore, in the present embodiment, a silicon nitride layer is used as the passivation layers PAS1 to PAS3 formed on the gate wiring GL1, and the silicon nitride layer is formed at 150° C. or higher and 250° C. or lower. This suppresses a large amount of hydrogen from diffusing during the deposition of the silicon nitride layer, and suppresses an excessive supply of hydrogen to the low resistance region OS2. As a result, it is possible to suppress the transistor Tr1 from being depleted. Hereinafter, a deposition method of the passivation layers PAS1 to PAS3 will be described.

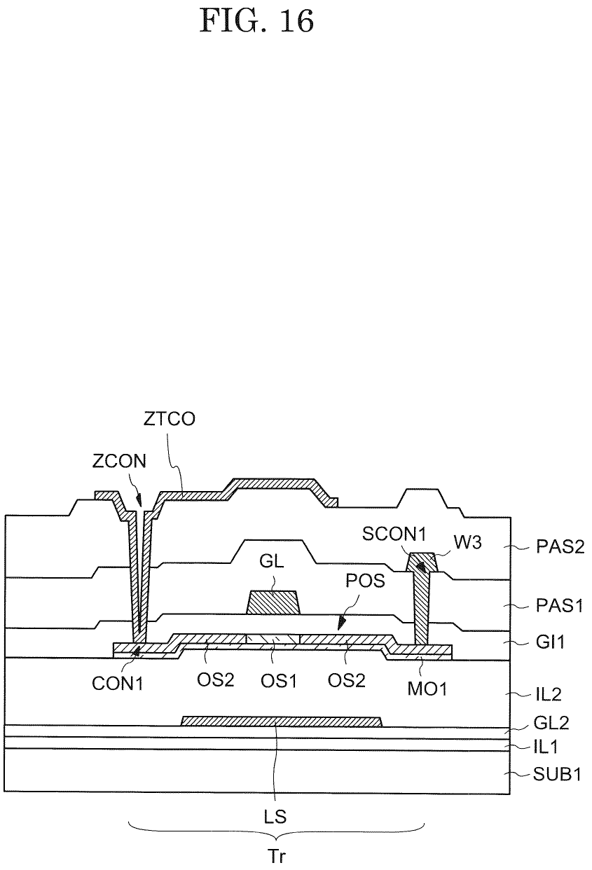

Next, the passivation layer PAS1 is deposited on the first gate insulating layer GI1 and the gate wiring GL1 (see step S1015 shown in FIG. 8 and FIG. 16). The passivation layer PAS1 is deposited using a silicon nitride layer. A thickness of the passivation layer PAS1 is 200 nm or more and 600 nm or less. In addition, the thickness of the passivation layer PAS1 is preferably larger than a thickness of the passivation layers PAS2 and PAS3. As a result, the parasitic capacitance generated in the wiring W3 can be reduced. The source gas at the time of depositing the silicon nitride layer contains a large amount of hydrogen. Therefore, when the deposition temperature exceeds 250° C., hydrogen diffuses and enters the oxide semiconductor layer POS. Therefore, in the case where the silicon nitride layer is deposited as the passivation layer PAS1, it is preferably deposited at 150° C. or higher and 250° C. or lower.

Next, the opening part SCON1 that reaches the low resistance region OS2 is formed in the passivation layer PAS1. Then, the wiring W3 is formed on the passivation layer PAS1, and the wiring W3 is connected to the low resistance region OS2 via the opening part SCON1 (see step S1016 shown in FIG. 8 and see FIG. 16). With regards to the deposition method of the wiring W3 and the conductive material, refer to the description of the light shielding layer LS. The deposition temperature of the wiring W3 is preferably a temperature that does not exceed the deposition temperature of the passivation layer PAS1. This is because hydrogen is released from the passivation layer PAS1, and the hydrogen diffuses into the channel region OS1 in the case where the film is formed at a temperature significantly higher than the deposition temperature of the wiring W3. In this way, it is preferable that the deposition temperature of the passivation layer PAS1 does not exceed the deposition temperature of the wirings, the electrodes, and the insulating layers formed on the passivation layer PAS1.

Next, the passivation layer PAS2 is deposited on the passivation layer PAS1 and the wiring W3 (see step S1017 shown in FIG. 8 and FIG. 16). The passivation layer PAS2 is formed using a silicon nitride layer. The thickness of the passivation layer PAS2 is 50 nm or more and 350 nm or less. Similar to the passivation layer PAS1, the silicon nitride layer of the passivation layer PAS2 is preferably formed at 150° C. or higher and 250° C. or less. As a result, when the passivation layer PAS2 is formed, the diffusion of hydrogen contained in the source gas can be suppressed, and the diffusion of hydrogen contained in the silicon nitride layer on the passivation layer PAS1 can be suppressed.

Next, the opening part ZCON that reaches the low resistance region OS2 is formed in the passivation layer PAS2. Then, the connecting electrode ZTCO is formed on the passivation layer PAS2, and the connecting electrode ZTCO is connected to the low resistance region OS2 via the opening part ZCON (see step S1018 shown in FIG. 8 and see FIG. 16).

The connecting electrode ZTCO is formed by processing an oxide conductive layer having light transmittance formed by the sputtering method. A transparent conductive material such as a mixture of indium oxide and tin oxide (ITO) or a mixture of indium oxide and zinc oxide (IZO) can be used as the connecting electrode ZTCO. A transparent conductive material other than the above may be used as the connecting electrode ZTCO.

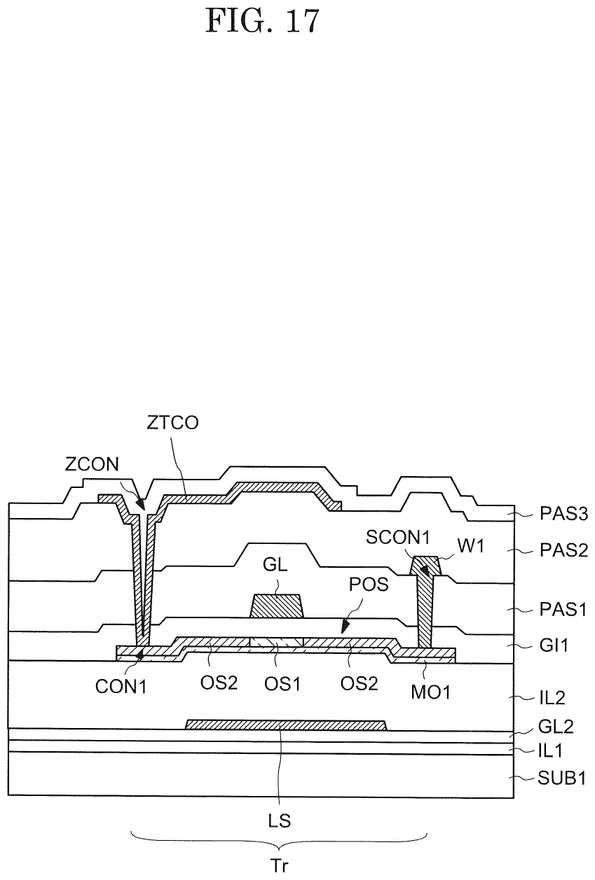

Next, the passivation layer PAS3 is deposited by using a silicon nitride layer in contact with the connecting electrode ZTCO (see step S1019 shown in FIG. 8 and see FIG. 17). The passivation layer PAS3 is deposited using a silicon nitride layer. The thickness of the passivation layer PAS3 is 50 nm or more and 300 nm or less. Similar to the passivation layer PAS1, the silicon nitride layer of the passivation layer PAS3 is preferably deposited at 150° C. or higher and 250° C. or lower. As a result, when the passivation layer PAS3 is deposited, the diffusion of hydrogen contained in the source gas can be suppressed, and the diffusion of hydrogen contained in the silicon nitride layer of the passivation layers PAS1 and PAS2 can be suppressed.

In addition, the silicon nitride layer as the passivation layer PAS3 is deposited at 150° C. or higher and 250° C. or lower, thereby suppressing the reduction of the connecting electrode ZTCO during the deposition. As a result, it is possible to suppress the occurrence of unevenness on the surface of the connecting electrode ZTCO. Short-circuiting of the connecting electrode ZTCO caused by the unevenness occurring on the surface of the connecting electrode ZTCO and a decrease in the transmittance of the light can be suppressed.

As described above, in the present embodiment, the silicon nitride layer is used as the passivation layers PAS1 to PAS3 formed on the gate wiring GL1, and the deposition temperature of the silicon nitride layer is set to 150° C. or higher and 250° C. or lower. As a result, since the excessive diffusion of hydrogen during the deposition of the passivation layers PAS1 to PAS3 can be suppressed, it is possible to appropriately supply hydrogen to the low resistance region OS2. In addition, since silicon oxide is not used as the passivation layers PAS1 to PAS3, the influence of the dust can be reduced. Furthermore, since the passivation layers PAS1 to PAS3 are formed only of the silicon nitride layer, the adhesion of the passivation layers PAS1 to PAS3 to each other can be improved. Furthermore, forming the silicon nitride layer as the passivation layers PAS1 to PAS3 at 150° C. or higher and 250° C. or lower makes it possible to suppress the generation of compressive stresses in the silicon nitride layer. As a result, it is possible to suppress peeling of the silicon nitride layer and the connecting electrode ZTCO and warpage of the substrate SUB1.

Next, the color filter CF is formed on the passivation layer PAS3 (see step S1020 shown in FIG. 8 and see FIG. 4). In the present embodiment, the color filter CF includes red, green, and blue colors. The color filters CF of the respective colors are arranged along the second direction D2.

Next, the third insulating layer IL3 is formed on the color filter CF (see step S1021 shown in FIG. 8 and see FIG. 4). The third insulating layer IL3 is formed using an organic resin material. Forming the third insulating layer IL3 on the color filter CF makes it possible to reduce the unevenness caused by the color filter CF and the transistor Tr1 formed below.

In the high-definition display device, since it is difficult to align the color filter formed on the counter substrate with the pixel circuit of the array substrate, it is preferable to arrange the color filter on the array substrate side. Furthermore, in order to make the surface on which the liquid crystal is driven flat, a planarization film is arranged on the color filter. The color filter and the planarization film are composed of an organic insulating material, but the organic insulating material contains a large amount of moisture. When this large amount of moisture enters the oxide semiconductor layer, the operation of the transistor is greatly affected, so that it is required to suppress the moisture from entering the oxide semiconductor layer.

In the present embodiment, a silicon nitride layer formed at 150° C. or higher and 250° C. or lower is used as the passivation layers PAS1 to PAS3. The silicon nitride layer can suppress the moisture contained in the color filter CF and the third insulating layer IL3 from entering the oxide semiconductor layer POS.

Next, the opening part PCON that reaches the connecting electrode ZTCO is formed in the third insulating layer IL3 and the color filter CF. Then, the pixel electrode PTCO is formed on the third insulating layer IL3, and the pixel electrode PTCO is connected to the connecting electrode ZTCO via the opening part PCON (see step S1022 shown in FIG. 8 and see FIG. 4). The pixel electrode PTCO is deposited by an inorganic insulating material and the deposition method described in the connecting electrode ZTCO.

Next, the fourth insulating layer IL4 is formed on the third insulating layer IL3 and the pixel electrode PTCO (see step S1023 shown in FIG. 8 and see FIG. 4). The fourth insulating layer IL4 is deposited by the inorganic insulating material and the deposition method described in the first insulating layer IL1. Since the fourth insulating layer IL4 functions as the capacitance of the capacitance element 168, it is preferable to be formed using, for example, a silicon nitride layer.

Next, the common auxiliary electrode CMTL is formed on the fourth insulating layer IL4 (see step S1024 shown in FIG. 8 and see FIG. 4). For an explanation of the deposition method and the conductive material of the common auxiliary electrode CMTL, refer the description of the light shielding layer LS. After the conductive film is formed on the fourth insulating layer IL4, the conductive film is processed so as to cover the gate wiring GL1 and the wiring W3, thereby forming the common auxiliary electrode CMTL arranged in a lattice pattern.

Next, the common electrode CTCO is formed on the common auxiliary electrode CMTL (see step S1025 shown in FIG. 8 and see FIG. 4). For an explanation of the deposition method of the common electrode CTCO and the transparent conductive material, refer to the description of the connecting electrode ZTCO. After the transparent conductive film is deposited on the fourth insulating layer IL4 and the common auxiliary electrode CMTL, the transparent conductive film is processed so as to overlap the common auxiliary electrode CMTL, thereby forming the common electrode CTCO arranged in a lattice pattern. The common electrode CTCO and the common auxiliary electrode CMTL serve as a common wiring. Since the common electrode CTCO is made of a transparent conductive material, the resistance is higher, but the resistance can be reduced by arranging the common auxiliary electrode CMTL in contact with the common electrode CTCO. In addition, since the common auxiliary electrode CMTL has a light-shielding effect, it also functions as a black matrix.

Next, the spacer SP is formed in the opening part PCON (see step S1026 shown in FIG. 8 and see FIG. 4). The spacer SP is formed by using an organic resin so that the organic resin protrudes from the substrate. The spacer SP may not be formed in all of the opening part PCON. In the case where the spacer SP is not formed, the organic resin is embedded in the opening part PCON, and the organic resin may not protrude from the surface.

Next, the alignment film OF1 is formed on the substrate SUB1, and the seal part 200 is applied so as to surround the display region 122, and a liquid crystal is dropped. The counter substrate SUB2 on which the black matrix BM or the like is formed and the substrate SUB1 are bonded so as to face each other, and the seal part 200 is cured. Through the above steps, the display device 10 can be manufactured.

In the present embodiment, a silicon nitride layer is used as the passivation layers PAS1 to PAS3 formed on the gate wiring GL1. Therefore, the passivation layer PAS2 is in contact with the passivation layer PAS1 and the passivation layer PAS3. The wiring W3 is sandwiched between the passivation layer PAS1 and the passivation layer PAS2, and the connecting electrode ZTCO is sandwiched between the passivation layer PAS2 and the passivation layer PAS3. This improves the adhesion of the passivation layers PAS1 to PAS3. In addition, the passivation layers PAS1 to PAS3 are deposited at a low temperature of 150° C. or higher and 250° C. or lower. As a result, the hydrogen contained in the source gas and the hydrogen contained in the silicon nitride layer can be prevented from diffusing due to the heat applied at the time of depositing the passivation layers PAS1 to PAS3. Furthermore, since silicon oxide is not used as the passivation layers PAS1 to PAS3, it is possible to suppress the dust at the time of the deposition.

### [6. Crystal Structure of Oxide Semiconductor Layer]

The oxide semiconductor layer POS described in the present embodiment contains the Poly-OS. A particle diameter of a crystal grain contained in the Poly-OS observed from the upper surface of the oxide semiconductor layer POS (or the thickness direction of the oxide semiconductor layer POS) is 0.1 μm or more, preferably 0.3 μm or more, and more preferably 0.5 μm or more. For example, the particle diameter of the crystal grain can be obtained using a cross-sectional SEM observation, a cross-sectional TEM observation, or an electron back scattered diffraction (EBSD) method.

In the Poly-OS method, the plurality of crystal grains may have one type of crystal structure, or may have a plurality of types of crystal structures. The crystal structure of the Poly-OS can be identified using an electron diffraction method or an XRD method, or the like. That is, the crystal structure of the oxide semiconductor layer POS can be identified by the electron diffraction method, or the XRD method, or the like.

The crystal structure of the oxide semiconductor layer POS is preferably cubic. The cubic crystal has a high degree of symmetry of the crystal structure, and even if an oxygen deficiency is generated in the oxide semiconductor layer POS, structural relaxation is unlikely to occur, and the crystal structure is stable. As described above, by increasing the ratio of indium, the crystal structure of each of the plurality of crystal grains is controlled, and the oxide semiconductor layer POS having a cubic crystal structure can be formed.

In the transistor Tr1 including the oxide semiconductor layer POS prepared by the above manufacturing methods, even when the channel length L of the channel region OS1 is 0.5 μm or more and 2.0 μm or less, good transistor properties can be obtained. Since a miniaturized transistor can be formed, the pixel circuit can also be miniaturized. As a result, it is possible to provide the high-definition display device 10.

In the transistor Tr including the oxide semiconductor layer POS manufactured by the above-described manufacturing method, it is possible to obtain an electric property having a mobility of 50 cm²/Vs or more, 55 cm²/Vs or more, or 60 cm²/Vs or more in a range where the channel length L of the channel region OS1 is 0.5 μm or more and 2 μm or less and the channel width of the channel region OS1 is 1 μm or more and 25 μm or less. The mobility in the present embodiment is the field-effect mobility in a saturated region of the transistor, and means the largest value of the field-effect mobility in a region where a potential difference (Vd) between the source electrode and the drain electrode is larger than the transistor (Vg−Vth) obtained by subtracting a threshold voltage (Vth) from a voltage (Vg) supplied to the gate electrode.

### [7. First Modification]

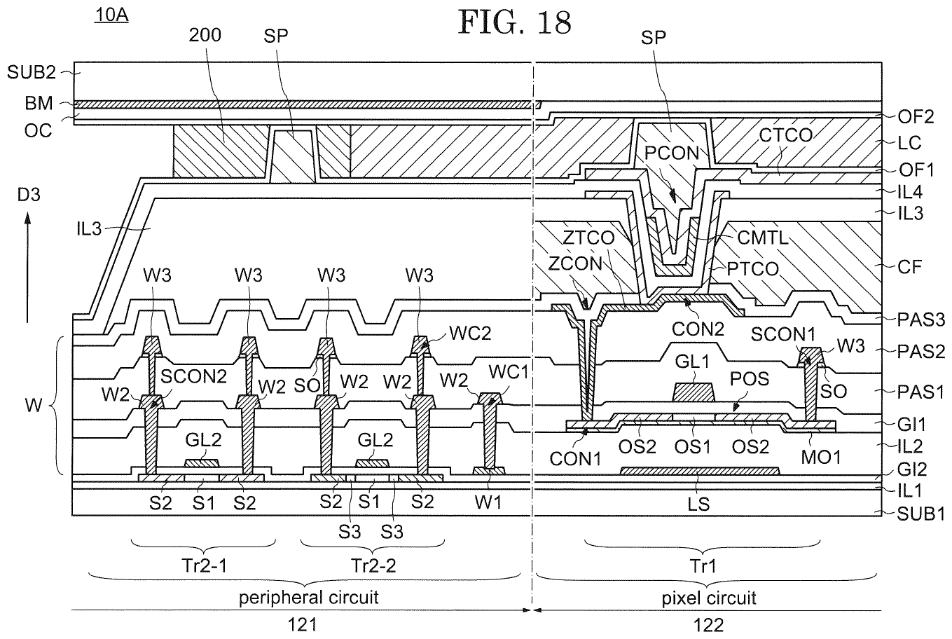

Next, a first modification of the display device 10 will be described with reference to FIG. 18 to FIG. 21. In the present embodiment, a configuration in which only a silicon nitride layer is used as the passivation layers PAS1 to PAS3, and silicon oxide is not used has been described. In the present modification, a silicon oxide layer SO is formed on the passivation layer PAS1.

FIG. 18 is a cross-sectional view showing an outline of a display device 10A according to an embodiment of the present invention. The display device 10A shown in FIG. 18 is different from the configuration of the display device 10 shown in FIG. 4 in that the silicon oxide layer SO is arranged between the passivation layer PAS1 and the wiring W3.

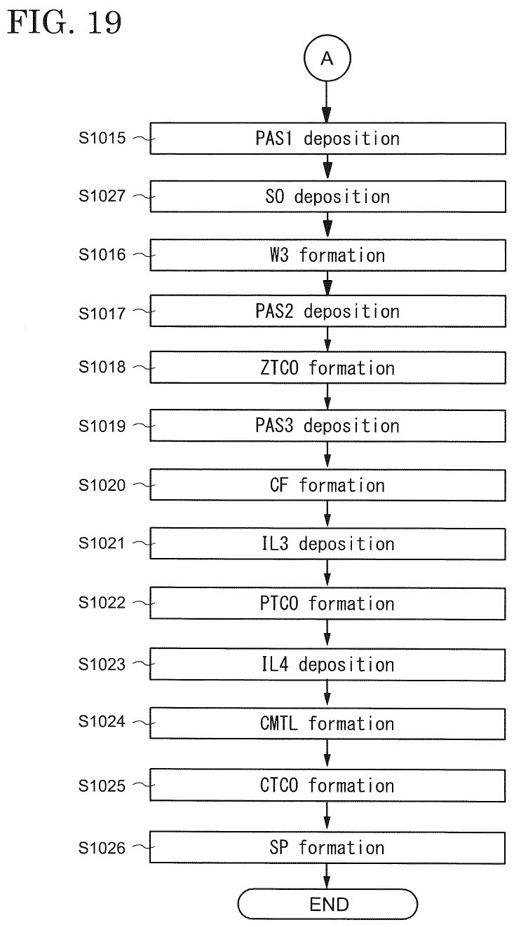

FIG. 19 is a sequence diagram illustrating a method of manufacturing the display device 10A according to an embodiment of the present invention. In the present modification, step S1027 and step S1016 different from the sequence diagrams shown in FIG. 7 and FIG. 8 will be described more specifically.

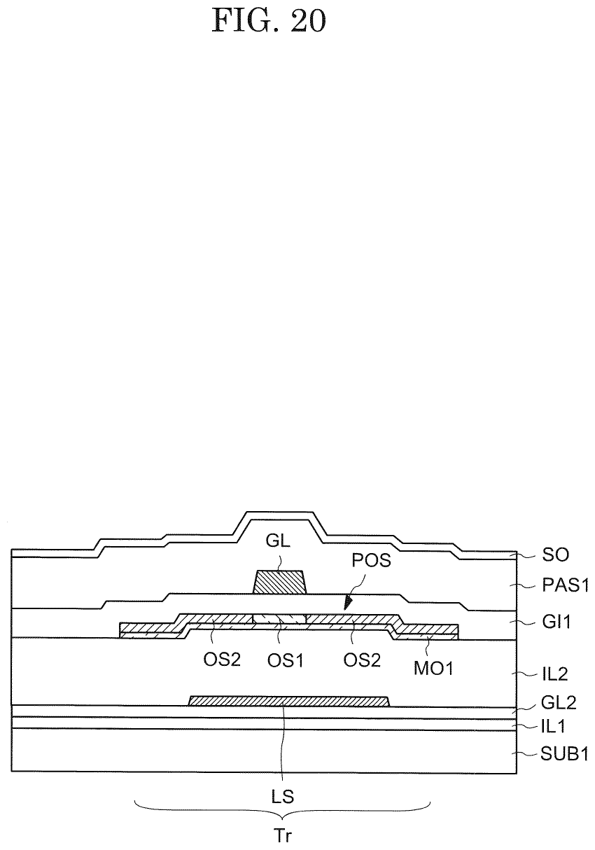

The silicon oxide layer SO is formed on the passivation layer PAS1 (see step S1027 shown in FIG. 19 and see FIG. 20). As described above, since the dust is generated when the silicon oxide layer is deposited, a thickness T1 of the silicon oxide layer SO is preferably smaller than the thickness of the passivation layers PAS1 to PAS3, and for example, it is preferably formed in a thickness of 10 nm or more and 50 nm, or 10 nm or more and 30 nm or less. As a result, generation of the dust during the deposition can be suppressed. In addition, the temperature at which the silicon oxide layer SO is formed is also set to 150° C. or higher and 250° C. or lower, so that it is possible to suppress the hydrogen contained in the passivation layer PAS1 from diffusing.

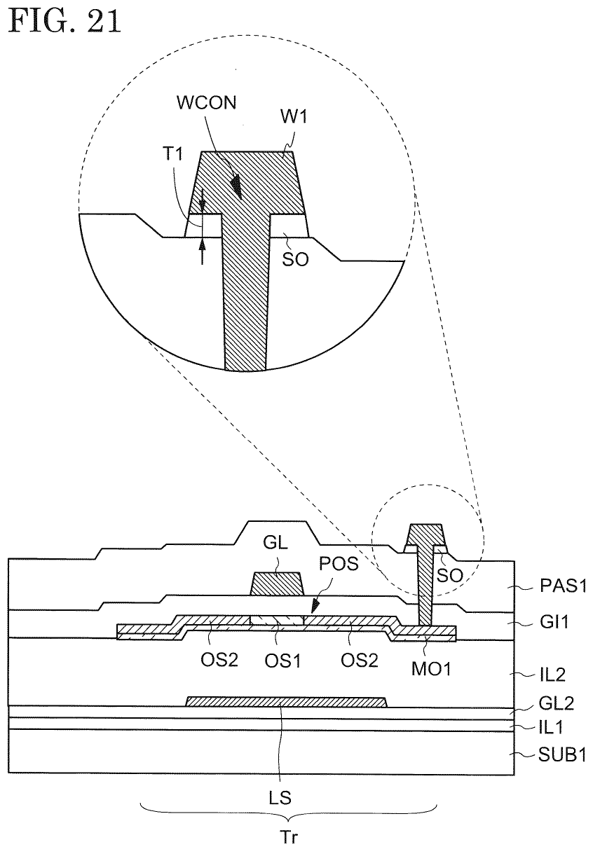

Next, the opening part SCON1 that reaches the low resistance region OS2 is formed in the passivation layer PAS1. After that, the wiring W3 is formed on the passivation layer PAS1, and the wiring W3 is connected to the low resistance region OS2 via the opening part SCON1 (see step S1016 shown in FIG. 8 and see FIG. 21). The deposition method of the wiring W3 and the conductive material may refer to the description of the light shielding layer LS. The wiring W3 can be formed by processing the conductive film, but the passivation layer PAS1 may also be etched when the conductive film is processed. By forming a thin silicon oxide layer SO on the passivation layer PAS1, the silicon oxide layer SO can function as an etching stopper.

In the present modification, all of the silicon oxide layer SO exposed from the wiring W3 is removed by etching. Therefore, as shown in FIG. 21, the silicon oxide layer SO is arranged between the passivation layer PAS1 and the wiring W3. Since the silicon oxide layer SO is masked by the wiring W3, it remains as thick as it was deposited. Therefore, the thickness T1 of the silicon oxide layer SO shown in FIG. 21 is 10 nm or more and 50 nm or less, or 10 nm or more and 30 nm or less. After that, a silicon nitride layer is deposited as the passivation layer PAS2 on the passivation layer PAS1, thereby improving the adhesion between the passivation layer PAS1 and the passivation layer PAS2. Therefore, in the present modification, in addition one of the advantages described in the manufacturing processes of FIG. 7 to FIG. 8 is that is it possible to suppress the passivation layer PAS1 from being etched more than necessary when the wiring W3 is processed.

### [8. Second Modification]

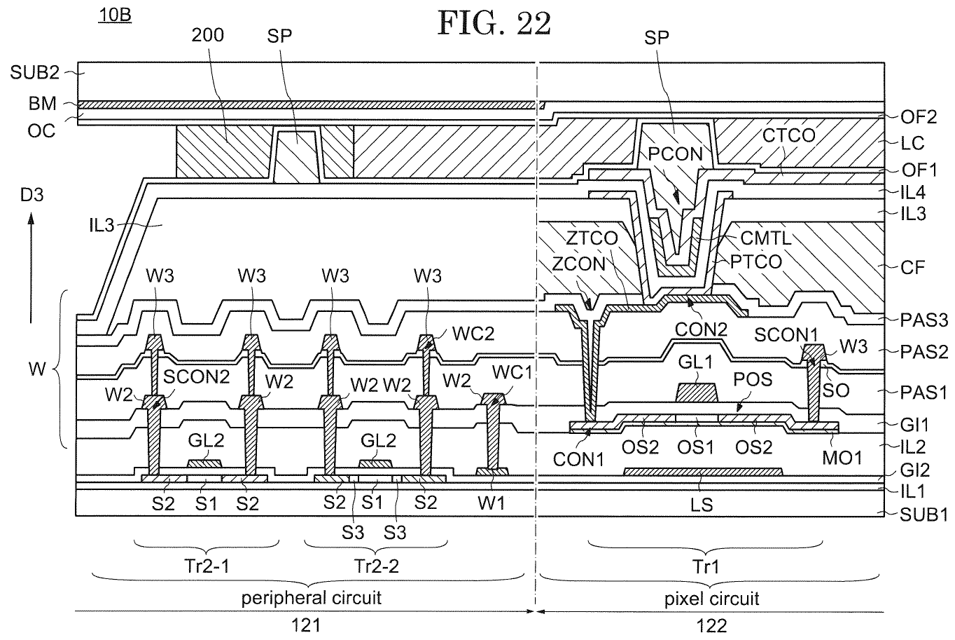

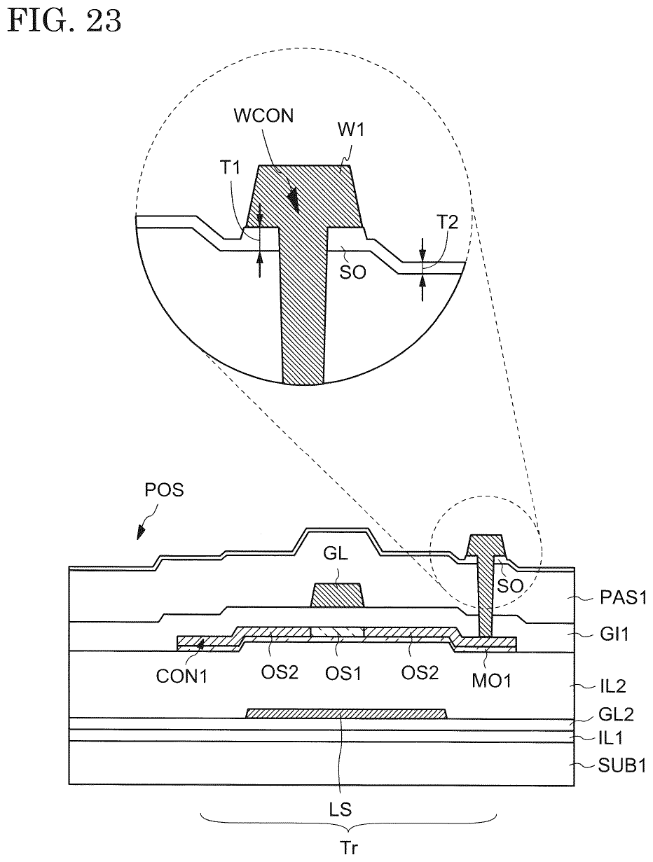

Next, the second modification of the display device 10 will be described with reference to FIG. 22 and FIG. 23. In the first modification, the case where the silicon oxide layer SO is formed on the passivation layer PAS1 and all of the silicon oxide layer SO exposed from the wiring W3 is removed when the wiring W3 is formed has been described. In the present modification, the case where the wiring W3 is processed so that the silicon oxide layer SO remains will be described. Therefore, the sequential diagram illustrating a manufacturing method of a display device 10B is substantially the same as that of FIG. 19.

FIG. 22 is a cross-sectional view showing an outline of the display device 10B according to an embodiment of the present invention. In the present modification, the silicon oxide layer SO is arranged between the passivation layer PAS1 and the passivation layer PAS2. In the silicon oxide layer SO, a thickness T1 of a first region overlapping the wiring W3 is larger than a thickness T2 of a second region not overlapping the wiring W3.

In the present modification, in the sequence diagram shown in FIG. 19, the step S1016 is different from that in the first modification. Since the silicon oxide layer SO is formed with a thickness of 10 nm or more and 50 nm or less, preferably 10 nm or more and 30 nm or less, the thickness T1 is a thickness with the silicon oxide layer SO formed. On the other hand, since the region exposed from the wiring W3 is removed by etching, the thickness T2 is smaller than the thickness T1. The thickness T2 may be greater than 0 nm and less than 10 nm. The conductive film is etched to form the wiring W3 so that the silicon oxide layer SO remains.

A thin silicon oxide layer SO is arranged between the passivation layer PAS1 and the passivation layer PAS2, so that the diffusion of hydrogen contained in the layer above the passivation layer PAS2 can be suppressed. In addition, since the thickness of the silicon oxide layer SO is smaller than the thickness of the passivation layers PAS1 to PAS3, the influence of the dust during the deposition can also be reduced.

### [9. Third Modification]

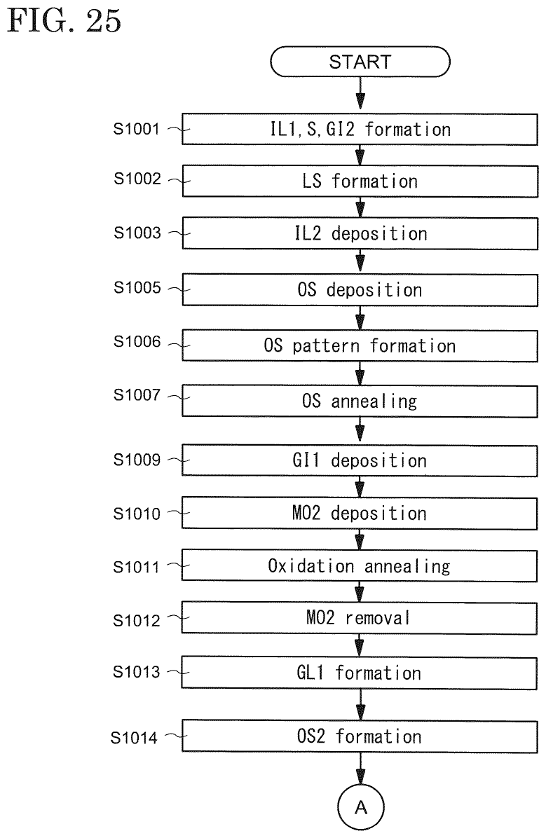

Next, a third modification of the display device 10 will be described with reference to FIG. 24 and FIG. 25. A manufacturing method partially different from the method of manufacturing the display device 10 will be described in the present modification.

FIG. 24 is a cross-sectional view showing an outline of a display device 10C according to an embodiment of the present invention. As shown in FIG. 24, the configuration of the transistor Tr1 is different from the configuration of the transistor Tr1 shown in FIG. 4. In FIG. 24, the metal oxide layer MO1 formed below the oxide semiconductor layer POS is omitted.

FIG. 25 is a sequence diagram illustrating a method of manufacturing the display device 10C according to an embodiment of the present invention. The sequence diagram shown in FIG. 25 is partially different from the sequence diagram shown in FIG. 7. As shown in FIG. 25, the process of forming the metal oxide layer MO1 formed on the second insulating layer IL2 (step S1004 shown in FIG. 7) and the process of patterning the metal oxide layer MO1 (step S1008 shown in FIG. 7) are omitted. In addition, since the process after the step S1014 shown in FIG. 25 is the same as the process shown in FIG. 8, a detailed explanation thereof is omitted. Although the metal oxide layer MO1 is omitted in the present modification, the first gate insulating layer GI1 is capped by the metal oxide layer MO2. As a result, since the oxygen released from the second insulating layer IL2 and the first gate insulating layer GI1 is capped by the metal oxide layer MO2 by the subsequent oxidation annealing, it is supplied to the upper surface and the lower surface of the oxide semiconductor layer POS, thereby repairing the oxygen deficiencies. Therefore, it is possible to supply oxygen efficiently to the oxygen deficiencies of the oxide semiconductor layer POS.

### [10. Fourth Modification]

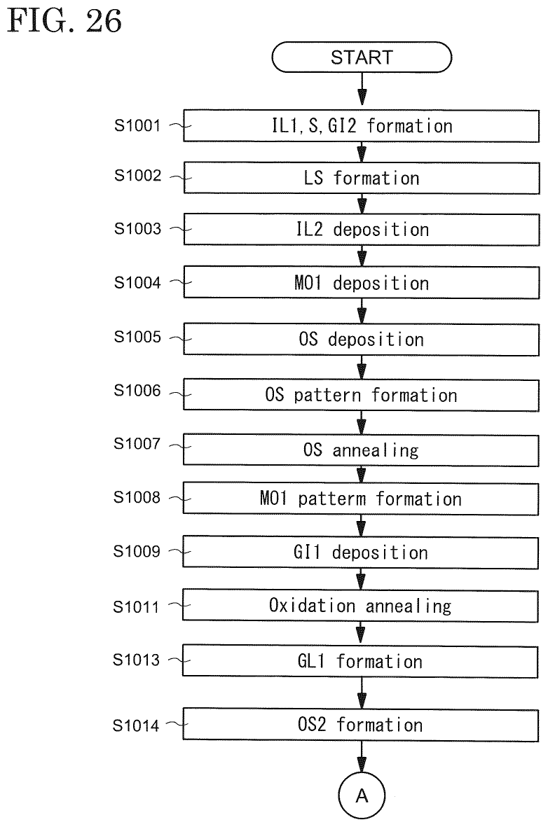

Next, a fourth modification of the display device 10 will be described with reference to FIG. 26. In the present modification, a manufacturing method that differs in part from the method of manufacturing the display device 10 will be described. In addition, since a cross-sectional structure of the display device according to the present modification is the same as the cross-sectional structure of the display device 10C shown in FIG. 24, the illustration thereof is omitted.

FIG. 26 is a diagram illustrating a method of manufacturing the display device according to an embodiment of the present invention. The sequence diagram shown in FIG. 26 is partially different from the sequence diagram shown in FIG. 7. As shown in FIG. 26, the process of forming the metal oxide layer MO2 formed on the first gate insulating layer GI1 (step S1010 shown in FIG. 7) and the process of removing the metal oxide layer MO2 (step S1012 shown in FIG. 7) are omitted. In addition, since the process after the step S1014 shown in FIG. 26 is the same as the process shown in FIG. 8, a detailed explanation thereof is omitted. In the present modification, the metal oxide layer MO2 is omitted, but the lower side of the oxide semiconductor layer POS is capped by the metal oxide layer MO1. As a result, the oxygen released from the second insulating layer IL2 is supplied to the upper surface and the lower surface of the oxide semiconductor layer POS by the subsequent oxidation annealing, thereby repairing the oxygen deficiencies. In addition, since the oxygen released from the second insulating layer IL2 is blocked by the metal oxide layer MO1 and is suppressed from being supplied to the lower surface of the oxide semiconductor layer POS in a large amount, formation of a defective level can be suppressed. Therefore, it is possible to supply oxygen efficiently to the oxygen deficiencies of the oxide semiconductor layer POS.

As described in the modification and the fourth modification, the annealing is performed in a state of forming the metal oxide layer MO1 or the metal oxide layer MO2 on at least one of the lower surface and the upper surface of the oxide semiconductor layer POS, so that oxygen can be supplied to the oxygen deficiencies of the oxide semiconductor layer POS.

Furthermore, in the method of manufacturing the display device 10 according to the third modification and the fourth modification, in the transistor Tr1 including the oxide semiconductor layer POS, good transistor properties can be obtained even when the channel length L of the channel region OS1 is 0.5 μm or more and 2 μm or less. Since a miniaturized transistor can be formed, the pixel circuit can also be miniaturized. As a result, it is possible to provide the high-definition the display device 10.

In the method of manufacturing the display device 10C according to the third modification and the fourth modification, it is also possible to form the oxide semiconductor layer POS having a good polycrystalline structure. In the transistor Tr including the oxide semiconductor layer POS manufactured in the third modification and the fourth modification, it is possible to obtain an electric property having a mobility of 30 cm²/Vs or more, 35 cm²/Vs or more, or 40 cm²/Vs or more in a range where the channel length L of the channel region is OS1 is 0.5 μm or more and 2 μm or less and the channel width of the channel region OS1 is 1 μm or more and 25 μm or less.

Each of the embodiments described above as an embodiment of the present invention can be appropriately combined and implemented as long as no contradiction is caused. Furthermore, the addition, deletion, or design change of components as appropriate by those skilled in the art based on the semiconductor device and the display device of the respective embodiments are also included in the scope of the present disclosure as long as they are provided with the gist of the present invention.

Furthermore, it is understood that, even if the effect is different from those provided by each of the above-described embodiments, the effect obvious from the description in the specification or easily predicted by persons ordinarily skilled in the art is apparently derived from the present invention.

What is claimed is:

1. A display device comprising:
an oxide semiconductor layer including a polycrystalline structure;
a gate insulating layer provided on the oxide semiconductor layer;
a gate electrode opposite to the oxide semiconductor layer on the gate insulating layer;
a first silicon nitride layer provided in contact with the gate electrode;
a source wiring provided in contact with the first silicon nitride layer and electrically connected to the oxide semiconductor layer;
a second silicon nitride layer provided in contact with the source wiring and the first silicon nitride layer;
a first transparent conductive layer provided in contact with the second silicon nitride layer and electrically connected to the oxide semiconductor layer; and
a third silicon nitride layer provided in contact with the first transparent conductive layer and the second silicon nitride layer,
wherein a channel length of the gate electrode is 2.0 μm or less.

2. The display device according to claim 1, further comprising:
a silicon oxide layer between the source wiring and the first silicon nitride layer.

3. The display device according to claim 2, wherein
a thickness of the silicon oxide layer is 10 nm or more and 50 nm or less.

4. The display device according to claim 1, further comprising:
an aluminum oxide layer between the gate insulating layer and the oxide semiconductor layer.

5. The display device according to claim 1, wherein
the oxide semiconductor layer contains two or more metal elements including indium, and the ratio of indium in the two or more metal elements is 50% or more.

6. A display device comprising:
an oxide semiconductor layer including a polycrystalline structure;
a gate insulating layer provided on the oxide semiconductor layer;
a gate electrode opposite to the oxide semiconductor layer on the gate insulating layer;
a first silicon nitride layer provided in contact with the gate electrode;
a silicon oxide layer provided in contact with the first silicon nitride layer;
a source wiring provided in contact with the silicon oxide layer and electrically connected to the oxide semiconductor layer; and
a second silicon nitride layer provided in contact with the source wiring and the first silicon nitride layer;
a first transparent conductive layer provided in contact with the second silicon nitride layer and electrically connected to the oxide semiconductor layer; and
a third silicon nitride layer provided in contact with the first transparent conductive layer and the second silicon nitride layer,
wherein
a channel length of the gate electrode is less than 2.0 μm, and
a thickness of the silicon oxide layer is less than each of a thickness of the first silicon nitride layer, a thickness of the second silicon nitride layer, and a thickness of the third silicon nitride layer.

7. The display device according to claim 6, wherein
a thickness of the first region overlapping the source wiring is larger than a thickness of the second region not overlapping the source wiring, in the silicon oxide layer.

8. The display device according to claim 7, wherein
a thickness of the first region of the silicon oxide layer is 10 nm or more and 50 nm or less.

9. The display device according to claim 7, wherein
a thickness of the second region of the silicon oxide layer is larger than 0 nm and less than 10 nm.

10. The display device according to claim 6, further comprising:
an aluminum oxide layer between the gate insulating layer and the oxide semiconductor layer.

11. The display device according to claim 6, wherein
the oxide semiconductor layer includes two or more metal elements including indium, and a ratio of the indium to the two or more metal elements is 50% or more.

12. A method of manufacturing a display device, the method comprising the steps of:
forming an oxide semiconductor layer including a polycrystalline structure;
depositing a gate insulating layer on the oxide semiconductor layer;
forming a gate electrode opposite the oxide semiconductor layer on the gate insulating layer;
depositing a first silicon nitride layer in contact with the gate electrode;
forming a source wiring in contact with the first silicon nitride layer, and electrically connected to the oxide semiconductor layer;
forming a second silicon nitride layer in contact with the source wiring and the first silicon nitride layer;
forming a first transparent conductive layer in contact with the second silicon nitride layer, and electrically connected to the oxide semiconductor layer; and
depositing a third silicon nitride layer in contact with the first transparent conducting layer and the second silicon nitride layer,
wherein
a channel length of a channel region overlapping the gate electrode is 2.0 μm or less, in the oxide semiconductor layer, and
a deposition temperature of each of the first silicon nitride layer, the second silicon nitride layer, and the third silicon nitride layer is 150° C. or more and 250° C. or less.
